(19) United States
(12) Patent Application Publication
(10) Pub. No.: US 2023/0282721 A1
(43) Pub. Date: Sep. 7, 2023

(54) SEMICONDUCTOR DEVICE AND ELECTRONIC APPARATUS

(71) Applicant: SONY SEMICONDUCTOR SOLUTIONS CORPORATION, KANAGAWA (JP)

(72) Inventors: YUKI YANAGISAWA, KANAGAWA (JP); KATSUHIKO TAKEUCHI, KANAGAWA (JP)

(21) Appl. No.: 18/006,622

(22) PCT Filed: May 26, 2021
(86) PCT No.: PCT/JP2021/020076

§ 371 Date: Jan. 24, 2023

(30) Foreign Application Priority Data
Aug. 5, 2020 (JP) 2020-133351

(51) Int. Cl. H01L 29/423; H01L 29/51; H01L 29/66; H01L 29/778; H01L 29/40

(52) U.S. Cl. CPC H01L 29/42368; H01L 29/401; H01L 29/42376; H01L 29/512; H01L 29/513; H01L 29/517; H01L 29/66462; H01L 29/778; H01L 29/2003

(57) ABSTRACT

Fluctuation and deterioration of characteristics of a semiconductor device are reduced. The semiconductor device includes a field effect transistor mounted on a semiconductor base. In addition, the field effect transistor includes an insulation layer that includes a first insulation film provided on a main surface of the semiconductor base, and a second insulation film provided on the first insulation film and having etching selectivity higher than etching selectivity of the first insulation film, a gate electrode that has a head part located on the insulation layer and a body part extending from the head part toward the main surface of the semiconductor base and is configured such that the head part has a width larger than a width of the body part, and an embedded film provided between the first insulation film and the body part of the gate electrode in a gate length direction of the gate electrode, and having a relative permittivity equal to or higher than a relative permittivity of the second insulation film.

### TECHNICAL FIELD

The present technology (the technology according to the present disclosure) relates to a semiconductor device and an electronic apparatus, and particularly to a technology which is effectively operative when applied to a semiconductor device and an electronic apparatus each including a field effect transistor.

### BACKGROUND ART

A GaN HEMT (High Electron Mobility Transistor), which is a field effect transistor mounted on a compound semiconductor substrate, has been attracting attention. Gallium nitride (GaN), which is a wide gap semiconductor material, has such characteristics as high breakdown voltage, operability at high temperature, and high saturated drift velocity. Moreover, a two-dimensional electron gas (2DEG) layer formed at GaN-based hetero junction has characteristics of high mobility and high sheet electron density. The GaN HEMT as a GaN-based hetero FET having these characteristics is capable of performing low-resistance, high-speed, and high-breakdown-voltage operations, and therefore is expected to be applied to power devices, RF (Radio Frequency) devices such as switches, and others used in 5G high-speed communication systems.

The GaN HEMT has a barrier layer above a channel layer. In a case of an ordinary GaN HEMT, AlGaN or AlInN is formed as a barrier layer above GaN corresponding to the channel layer. For controlling current flowing between a drain and a source, an insulation film is formed in an upper part of the barrier layer, and a gate metal (gate electrode) is formed above the insulation film.

The GaN HEMT exhibits phenomena of fluctuation of characteristics, such as a drain-lag and a shift of a threshold voltage Vth, due to physical properties and crystalline of the GaN HEMT. When a negative bias is applied to a gate of a device to apply off stress (high electric field), electrons are captured in a film or inside a semiconductor. Accordingly, drain current (Id) at this time appears to be more deteriorated than that during ordinary DC measurement. In this case, traps release electrons with a certain time constant. Accordingly, responsiveness of current to voltage lowers. This phenomenon is called the drain-lag. Moreover, the Vth shift is a phenomenon of deviation from original Vth as a result of traps or de-traps of carriers similarly produced by a trigger of an electric field. Fluctuation of characteristics influences extraction or design of a model.

It is effective to relieve concentration of an electric field to reduce fluctuation of characteristics. In general, an electric field is most concentrated on a gate end when bias is applied to a gate. For avoiding this concentration, a field plate structure has conventionally been used, and the field plate structure has a gate metal projected from an opening toward the outside to promote depletion inside a semiconductor immediately below the gate metal, and thereby smoothen electric field distribution.

Note that the following PTL 1 to PTL 3 are presented in a citation list associated with the present technology.

### CITATION LIST

### Patent Literature

PTL 1] Japanese Patent Laid-Open No. Hei 09-027505
PTL 2] Japanese Patent Laid-Open No. 2008-98400
PTL 3] Japanese Patent Laid-Open No. 2017-54960

### SUMMARY

### Technical Problems

Meanwhile, for conventional manufacture of a semiconductor device including the GaN HEMT described above, a gate insulation film and an insulation film are formed on a semiconductor (barrier layer) surface, and a gate opening for defining a gate length (Lg) is formed by dry-etching of this insulation film. Thereafter, a T-shaped gate electrode is formed with use of the gate opening. The T-shaped gate electrode has a body part penetrating the insulation film, and a head part having a larger width than a width of the body part and located on the insulation film.

However, when the semiconductor surface is damaged by dry-etching, many levels are produced in an interface with the gate insulation film. Specifically, exposure to plasma during etching and entrance of ions or the like contained in etching gas into the semiconductor have adverse effects. As a result, traps or de-traps of carriers are produced, and cause characteristic fluctuation. Further, the etching damage given to the surface increases sheet resistance, and deteriorates off-characteristics, i.e., causes an increase in leak current and lowering of breakdown voltage.

For preventing this surface damage, it is effective to form a second insulation film above the first insulation film, and form an opening by double steps, i.e., an initial step of performing dry etching reaching an intermediate position of the first insulation film from the second insulation film, and a subsequent step of performing wet-etching after the dry etching. In this case, it is important to form an opening only in the first insulation film without etching the second insulation film which defines the gate length. In this case, however, the first insulation film is withdrawn by wet-etching which is isotropic etching. Accordingly, a hollow portion is formed on the side of the body part of the gate electrode. This hollow portion is effective in view of reduction of gate capacitance.

However, an effect produced by a field plate including a projected portion of the head part of the gate electrode for the purpose of relief of an electric field generated in the semiconductor surface increases as combined capacitance from the projected portion of the head part of the gate electrode to the semiconductor surface in the longitudinal direction increases. This is because carriers induced in the semiconductor surface by the gate electrode are allowed to increase.

However, when the hollow portion (relative permittivity εr = 1) is formed on the side of the body part of the gate electrode, the capacitance lowers. As a consequence, the relief of the electric field becomes insufficient by the decrease in the field plate effect. As a result, reduction of fluctuation of characteristics caused by the trigger of the electric field becomes difficult.

Moreover, when the thickness of the first insulation film is reduced for the purpose of increasing the capacitance, the surface is still damaged by dry etching. Further, when the permittivity of the entire first insulation film is raised, the gate capacitance increases. As a result, a cutoff frequency ft, which is a characteristic necessary for a power amplifier, deteriorates. In addition, even when these countermeasures are applied, the electric field relieving effect is not considered to be sufficient since the hollow portion immediately below the projected portion of the head part of the gate electrode is dominant.

An object of the present technology is to provide a technology capable of reducing fluctuation of characteristics and deterioration of characteristics.

### Solution to Problems

A semiconductor device according to an aspect of the present technology includes a field effect transistor mounted on a semiconductor base, in which the field effect transistor includes an insulation layer that includes a first insulation film provided on a main surface of the semiconductor base, and a second insulation film provided on the first insulation film and having etching selectivity higher than etching selectivity of the first insulation film, a gate electrode that has a head part located on the insulation layer, and a body part extending from the head part toward the semiconductor base, and that is configured such that the head part has a width larger than a width of the body part, and an embedded film provided between the first insulation film and the body part of the gate electrode in a gate length direction of the gate electrode, and having a relative permittivity equal to or higher than a relative permittivity of the second insulation film.

A semiconductor device according to another aspect of the present technology includes a field effect transistor mounted on a semiconductor base, in which the field effect transistor includes an insulation layer that includes a first insulation film provided on a main surface of the semiconductor base, and a second insulation film provided on the first insulation film and having etching selectivity higher than etching selectivity of the first insulation film, a gate electrode that has a head part located on the insulation layer, and a body part extending from the head part toward the main surface of the semiconductor base, and that is configured such that the head part has a width larger than a width of the body part, and a third insulation film provided between the first insulation film and the body part of the gate electrode and between the semiconductor base and the body part of the gate electrode in a gate length direction of the gate electrode, and having a relative permittivity equal to or higher than a relative permittivity of the second insulation film.

An electronic apparatus according to a further aspect of the present technology includes the semiconductor device.

### BRIEF DESCRIPTION OF DRAWINGS

FIG. 1 is a chip layout diagram depicting a configuration example of a semiconductor device according to a first embodiment of the present technology.

FIG. 2 is a plan diagram schematically depicting a configuration example of a transistor mounted on the semiconductor device according to the first embodiment of the present technology.

FIG. 3 is a cross-sectional diagram schematically depicting a configuration example of a cross-sectional structure taken along a section line II-II in FIG. 1.

FIG. 4 is an enlarged cross-sectional diagram depicting a part of FIG. 3.

FIG. 5A is a diagram presenting a relation between a relative permittivity of an embedded film and a capacitance ratio of a gate electrode.

FIG. 5B is a diagram presenting film thickness dependency of the embedded film concerning combined capacitance.

FIG. 5C is a diagram presenting film thickness dependency of a silicon oxide film concerning combined capacitance.

FIG. 6A is a step cross-sectional diagram of a manufacturing method of the semiconductor device according to the first embodiment of the present technology.

FIG. 6B is a step cross-sectional diagram continuing from FIG. 6A.

FIG. 6C is a step cross-sectional diagram continuing from FIG. 6B.

FIG. 6D is a step cross-sectional diagram continuing from FIG. 6C.

FIG. 6E is a step cross-sectional diagram continuing from FIG. 6D.

FIG. 6F is a step cross-sectional diagram continuing from FIG. 6E.

FIG. 6G is a step cross-sectional diagram continuing from FIG. 6F.

FIG. 6H is a step cross-sectional diagram continuing from FIG. 6G.

FIG. 6I is a step cross-sectional diagram continuing from FIG. 6H.

FIG. 7A is a cross-sectional diagram schematically depicting a configuration example of a transistor mounted on a semiconductor device according to a first modification of the first embodiment of the present technology.

FIG. 7B is a cross-sectional diagram schematically depicting a configuration example of a transistor mounted on a semiconductor device according to a second modification of the first embodiment of the present technology.

FIG. 7C is a cross-sectional diagram schematically depicting a configuration example of a transistor mounted on a semiconductor device according to a third modification of the first embodiment of the present technology.

FIG. 8 is a cross-sectional diagram schematically depicting a configuration example of a transistor mounted on a semiconductor device according to a second embodiment of the present technology.

FIG. 9A is a step cross-sectional diagram of a manufacturing method of the semiconductor device according to the second embodiment of the present technology.

FIG. 9B is a step cross-sectional diagram continuing from FIG. 9A.

FIG. 9C is a step cross-sectional diagram continuing from FIG. 9B.

FIG. 10 is a cross-sectional diagram schematically depicting a configuration example of a transistor mounted on a semiconductor device according to a third embodiment of the present technology.

FIG. 11A is a step cross-sectional diagram of a manufacturing method of the semiconductor device according to the third embodiment of the present technology.

FIG. 11B is a step cross-sectional diagram continuing from FIG. 11A.

FIG. 11C is a step cross-sectional diagram continuing from FIG. 11B.

FIG. 12 is a cross-sectional diagram schematically depicting a configuration example of a transistor mounted on a semiconductor device according to a fourth embodiment of the present technology.

FIG. 13 is a cross-sectional diagram schematically depicting a configuration example of a transistor mounted on a semiconductor device according to a fifth embodiment of the present technology.

[FIG. 14] FIG. 14 is a cross-sectional diagram schematically depicting a configuration example of a transistor mounted on a semiconductor device according to a sixth embodiment of the present technology.

FIG. 15 is a cross-sectional diagram schematically depicting a configuration example of a transistor mounted on a semiconductor device according to a seventh embodiment of the present technology.

FIG. 16 is a cross-sectional diagram schematically depicting a configuration example of a transistor mounted on a semiconductor device according to an eighth embodiment of the present technology.

FIG. 17 is an enlarged cross-sectional diagram depicting a part of FIG. 16.

FIG. 18A is a step cross-sectional diagram of a manufacturing method of the semiconductor device according to the first embodiment of the present technology.

FIG. 18B is a step cross-sectional diagram continuing from FIG. 18A.

FIG. 18C is a step cross-sectional diagram continuing from FIG. 18B.

FIG. 18D is a step cross-sectional diagram continuing from FIG. 18C.

FIG. 19 is a diagram presenting a comparison of an Id deterioration rate under off-stress between a field effect transistor of a comparative example and the field effect transistor of the eighth embodiment.

FIG. 20 is a diagram presenting a comparison of breakdown voltage between the field effect transistor of the comparative example and the field effect transistor of the eighth embodiment.

FIG. 21 is a diagram presenting a relation between combined capacitance and an Id deterioration rate.

FIG. 22 is a cross-sectional diagram schematically depicting a configuration example of a transistor mounted on a semiconductor device according to a modification 8-1 of the eighth embodiment of the present technology.

FIG. 23 is a cross-sectional diagram schematically depicting a configuration example of a transistor mounted on a semiconductor device according to a modification 8-2 of the eighth embodiment of the present technology.

FIG. 24 is a block diagram depicting an example of a configuration of a wireless communication device to which the semiconductor device of the present technology is applied.

### DESCRIPTION OF EMBODIMENTS

Embodiments of the present technology will hereinafter be described in detail with reference to the drawings.

Note that parts having identical functions are given identical reference signs in all the figures for explaining the embodiments of the present technology. Repetitive explanation of these parts will be omitted.

Moreover, the respective figures are only schematic figures and include illustrations different from reality in some cases. Further, the embodiments presented below are only examples of devices and methods for embodying the technical ideas of the present technology, and do not limit configurations to those described below. Accordingly, the technical ideas of the present technology can be modified in various manners within the technical scope described in the claims.

### First Embodiment

Described in a first embodiment will be an example of a semiconductor device to which the present technology is applied, on which device field effect transistors are mounted to relieve concentration of an electric field on a semiconductor surface.

### <<Configuration of Semiconductor Device>>

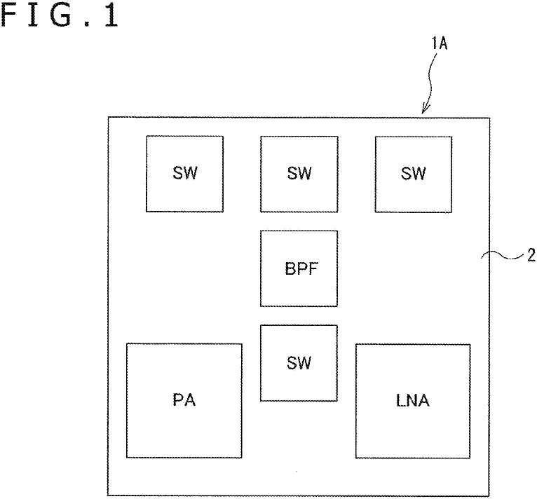

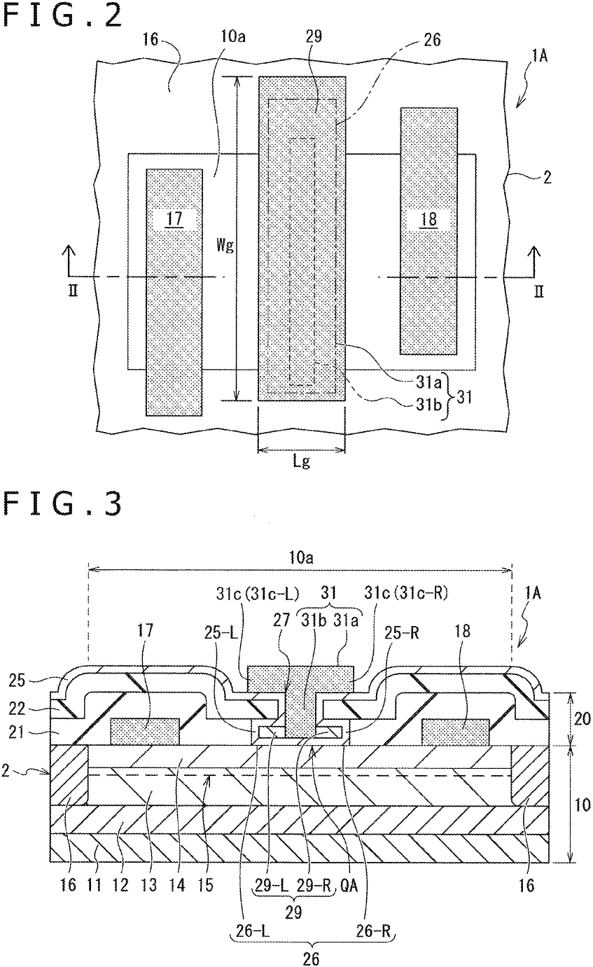

As depicted in FIG. 1, a semiconductor device 1A according to the first embodiment of the present technology chiefly includes a semiconductor chip 2 which has a square two-dimensional planar shape as viewed in a planar view. The semiconductor chip 2 includes a high-frequency power amplifier unit PA, a high-frequency low noise amplifier unit LNA, a high-frequency filter unit BPF, and high-frequency switch units SW. A field effect transistor QA depicted in FIGS. 2 and 3 is mounted on each of the high-frequency switch units SW as an element constituting a high-frequency switch. The field effect transistor QA depicted in FIGS. 2 and 3 is mounted on the high-frequency power amplifier unit PA as an element constituting a high-frequency power amplifier.

As depicted in FIG. 3, the semiconductor chip 2 includes a semiconductor base 10 and an insulation layer 20 provided on a main surface of the semiconductor base 10.

The semiconductor base 10 includes a substrate 11, a buffer layer 12 formed on the substrate 11, a channel layer 13 formed on the buffer layer 12, and a barrier layer (obstruction layer) 14 formed on the channel layer 13. In addition, an active region 10a sectioned by a non-active region 16 is provided in the main surface of the semiconductor base 10. For example, the non-active region 16 includes an impurity diffusion region where boron (B⁺) ions are diffused as impurities. Besides, as depicted in FIG. 3, the non-active region 16 reaches a position deeper than a two-dimensional electron gas (2DEG: Two Dimensional Electron Gas) layer 15 described below in a depth direction from the main surface of the semiconductor base 10. Insulation separation (element separation) between the active regions may be achieved by methods other than ion implantation. For example, insulation separation between the active regions may be achieved by dividing the channel layer 13 by dry etching.

The substrate 11 includes a semiconductor material. For example, the substrate 11 thus configured includes a III-V group compound semiconductor material. For example, the substrate 11 includes a semi-insulating monocrystal GaN (gallium nitride) substrate. The substrate 11 may include a substrate material having a lattice constant different from a lattice constant of the channel layer 13. For example, the substrate 11 thus configured has a constituent material such as SiC (silicon carbide), sapphire, or Si (silicon). In this case, the lattice constant is adjusted by the buffer layer 12 between the substrate 11 and the channel layer 13.

The buffer layer 12 includes a compound semiconductor layer formed by epitaxial growth on the substrate 11, for example, and includes a compound semiconductor which achieves lattice matching with the substrate 11 in a preferable manner. For example, an epitaxial growth layer including u-GaN to which no impurities are added (“u-” represents no addition of impurities; the same is applicable hereinafter) is formed on the substrate 11 including a monocrystal GaN substrate. Even when the lattice constant of the substrate 11 is different from the lattice constant of the channel layer 13, the buffer layer 12 provided between the substrate 11 and the channel layer 13 improves a crystal state of the channel layer 13, and can reduce a warp of a wafer. For example, when the substrate 11 and the channel layer 13 include Si and GaN, respectively, the buffer layer 12 can include AlN (aluminum nitride), AlGaN (aluminum gallium nitride), GaN, or others, for example. The buffer layer 12 may include a single layer, or may have a layered structure. When the buffer layer 12 includes a ternary material, respective compositions may be gradually varied within the buffer layer 12.

The channel layer 13 between the buffer layer 12 and the barrier layer 14 is a current path between a pair of main electrodes 17 and 18 functioning as a source electrode and a drain electrode. Carriers are accumulated in the channel layer 13 by polarization from the barrier layer 14. The two-dimensional electron gas (2DEG: Two Dimensional Electron gas) layer 15 is provided in the vicinity of a junction surface (hetero junction interface) with the barrier layer 14. It is preferable that the channel layer 13 thus configured include a compound semiconductor material where carriers are easily accumulated by polarization from the barrier layer 14. For example, the channel layer 13 includes GaN formed by epitaxial growth on the buffer layer 12. The channel layer 13 may include u-GaN to which no impurities are added. The channel layer 13 including u-GaN can reduce impurity scattering of carriers within the channel layer 13. Accordingly, mobility of carriers can be increased.

As depicted in FIG. 3, the insulation layer 20 includes a first insulation film 21 formed on the main surface of the semiconductor base 10, a second insulation film 22 formed on the first insulation film 21, and a third insulation film 25 formed on the second insulation film 22. For example, the first insulation film 21 includes an aluminum oxide (Al₃O₂) film. For example, the second insulation film 22 includes a silicon oxide (SiO₂) film having etching selectivity higher than etching selectivity of the first insulation film 21. For example, the first insulation film 21 has a film thickness ranging from 10 nm to 80 nm, such as a film thickness of 70 nm. For example, the second insulation film 22 has a film thickness ranging from 60 nm to 80 nm, such as a film thickness of 80 nm. Moreover, the first insulation film 21 has a relative permittivity equal to or higher than a relative permittivity of the second insulation film 22. For example, in a case where the first insulation film 21 and the second insulation film 22 include an aluminum oxide film and a silicon oxide film, respectively, the first insulation film 21 has a relative permittivity higher than the relative permittivity of the second insulation film 22.

The third insulation film 25 is so formed as to cover the first insulation film 21, the second insulation film 22, and the main surface of the semiconductor base 10 (barrier layer 14) within a chamber 26 described below. The third insulation film 25 includes a material which has a property of insulation from the barrier layer 14, the first insulation film 21, and the second insulation film 22 exposed to the chamber 26, which protects the barrier layer 14 from impurities such as ions, and which forms a preferable interface with the barrier layer 14 to reduce deterioration of characteristics of the device. For example, the third insulation film 25 includes laminated films of an Al₂O₃ film or a hafnium oxide (HfO₂) film each having a film thickness of approximately 10 nm and laminated in this order from the main surface side of the semiconductor base 10. The third insulation film 25 may include a single film including Al₂O₃ or HfO₂. Here, a portion of the third insulation film 25 interposed between the barrier layer 14 and the gate electrode 31 functions as a gate insulation film.

As depicted in FIGS. 2 and 3, the field effect transistor QA is formed in the active region 10a of the main surface of the semiconductor base 10. The field effect transistor QA includes the buffer layer 12, the channel layer 13, the barrier layer 14, and the two-dimensional electron gas layer 15. The field effect transistor QA further includes the pair of main electrodes 17 and 18 provided on the active region 10a of the main surface of the semiconductor base 10 at positions away from each other and functioning as a source electrode and a drain electrode, the chamber 26 provided in the insulation layer 20 and sandwiched between the pair of main electrodes 17 and 18, and an embedded film 29 filling the chamber 26. The field effect transistor QA further includes a gate electrode 31 which has a head part 31a located on the insulation layer 20 and a body part 31b protruding from the head part 31a to the chamber 26 through the insulation layer 20 and extending toward the main surface of the semiconductor base 10. The head part 31a has a width larger than a width of the body part 31b. Specifically, the field effect transistor QA of the first embodiment is a GaN-based hetero FET (HFET: Hetero Field Effect Transistor).

As depicted in FIG. 2, the gate electrode 31 has a long shape as viewed in the plan view. A gate width Wg is larger than a gate length Lg corresponding to a channel length. Moreover, the gate electrode 31 extends along the active region 10a and the non-active region 16. Further, as depicted in FIG. 3, the head part 31a of the gate electrode 31 is located on the third insulation film 25, and the body part 31b formed integrally with the head part 31a protrudes to the chamber 26 through a gate opening 27 formed in the insulation layer 20, and extends toward the main surface of the semiconductor base 10. In addition, the head part 31a has a width larger than the width of the body part 31b. Accordingly, the head part 31a includes projected portions 31c projected in directions away from each other from the body part 31b in the gate length direction of the gate electrode 31. The projected portions 31c include a first projected portion 31c-L located on one side surface side of the body part 31b (left side in FIG. 3), and a second projected portion 31c-R located on the other side surface side of the body part 31b (right side in FIG. 3).

Moreover, the width of the body part 31b in the gate length direction is larger on the semiconductor base 10 side than on the head part 31a side. Further, the width of the body part 31b in the gate length direction on the semiconductor base 10 side is larger than the width of the gate opening 27.

As depicted in FIGS. 2 and 3, the pair of main electrodes 17 and 18 are located away from each other in the gate length direction of the gate electrode 31 (a short direction or a width direction of the gate electrode 31) in a state where the gate electrode 31 is disposed between the main electrodes 17 and 18. Moreover, the pair of main electrodes 17 and 18 extend through the active region 10a and the non-active region 16 in the gate width direction of the gate electrode 31A (a long direction or a length direction of the gate electrode 31).

As described below, the chamber 26 is formed by withdrawal of the first insulation film 21 as a result of side etching performed when the gate opening defining the gate length of the gate electrode 31 is formed in the insulation layer 20. As depicted in FIG. 2, a planar pattern of the chamber 26 as viewed in the plan view is an annular planar pattern surrounding the body part 31b of the gate electrode 31. Accordingly, as depicted in FIG. 3, the chamber 26 includes a first portion 26-L located on one side surface side of the body part 31b (left side in FIG. 3), and a second portion 26-R located on the other side surface side of the body part 31b (right side in FIG. 3) in the gate length direction of the gate electrode 31. In addition, an inner surface of the chamber 26 is covered with the third insulation film 25.

The chamber 26 has a width larger than each width of the body part 31b of the gate electrode 31 and the gate opening 27 in the gate length direction of the gate electrode 31. Moreover, the chamber 26 has a width smaller than a width of the head part 31a of the gate electrode 31 in the gate length direction of the gate electrode 31. In other words, a contour of the chamber 26 as viewed in the plan view is located outside a contour of the gate opening 27, but inside a contour of the head part 31a of the gate electrode 31.

The embedded film 29 is an insulation film allowing wet-etching. Moreover, the embedded film 29 includes a material different from a material of the first insulation film 21. For example, in a case where the first insulation film 21 includes an aluminum oxide (Al₃O₂) film, for example, the embedded film 29 may include a single layer film which is any one of a zirconium oxide (ZrO₂) film, a lanthanum oxide (La₂O₃) film, and an yttrium oxide (Y₂O₃) film, or a laminated film containing at least any two of these films, for example.

Moreover, the embedded film 29 has a relative permittivity equal to or higher than the relative permittivity of the first insulation film 21. For example, the relative permittivity of the embedded film 29 is 10 or higher.

As depicted in FIG. 2, the embedded film 29 fills the chamber 26. A planar pattern of the embedded film 29 filling the chamber 26 as viewed in the plan view is an annular planar pattern surrounding the body part 31b of the gate electrode 31. Accordingly, as depicted in FIG. 3, the embedded film 29 includes a first portion 29-L located on one side surface side of the body part 31b (left side in FIG. 3), and a second portion 29-R located on the other side surface side of the body part 31b (right side in FIG. 3) in the gate length direction of the gate electrode 31. The first portion 29-L of the embedded film 29 fills the first portion 26-L of the chamber 26, while the second portion 29-R of the embedded film 29 fills the second portion 26-R of the chamber 26.

Moreover, the chamber 26 filled with the embedded film 29 is formed by withdrawal of the first insulation film 21 as a result of side etching performed at the time of formation of the gate opening 27. Accordingly, the embedded film 29 is provided between the first insulation film 21 and the body part 31b of the gate electrode 31 in the gate length direction of the gate electrode 31. Each of the first portion 29-L and the second portion 29-R of the embedded film 29 is provided between the first insulation film 21 and the body part 31b of the gate electrode 31. Moreover, as depicted in FIG. 3, one end of each of the first portion 29-L and the second portion 29-R of the embedded film 29 comes into contact with the body part 31b of the gate electrode 31 in the gate length direction of the gate electrode 31.

As depicted in FIG. 3, the inner surface of the chamber 26 is covered with the third insulation film 25. Accordingly, the third insulation film 25 lies between the embedded film 29 and the first insulation film 21. The third insulation film 25 includes a first portion 25-L and a second portion 25-R. The first portion 25-L of the third insulation film 25 is present between the first portion 29-L of the embedded film 29 and the first insulation film 21, while the second portion 25-R of the third insulation film 25 is present between the second portion 29-R of the embedded film 29 and the first insulation film 21. In this manner, the embedded film 29 and the first insulation film 21 are separated from each other by the third insulation film 25.

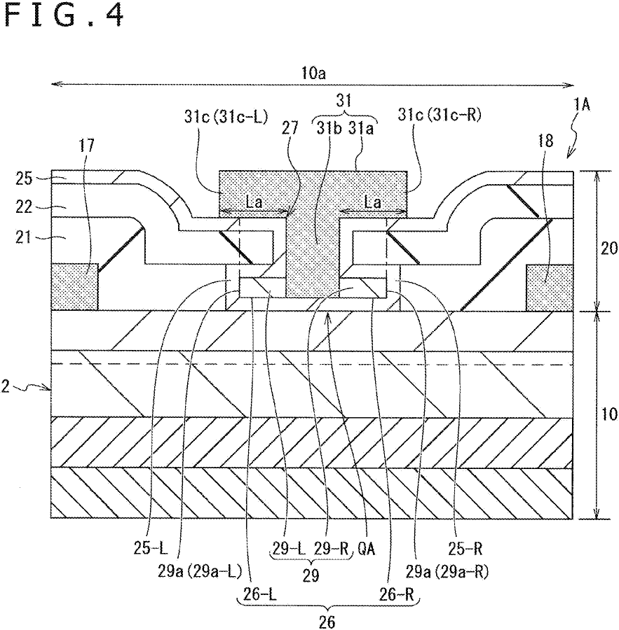

Moreover, as depicted in FIGS. 3 and 4, the embedded film 29 is provided between the head part 31a of the gate electrode 31 and the semiconductor base 10. The first portion 29-L of the embedded film 29 is provided between the first projected portion 31c-L of the head part 31a of the gate electrode 31 and the semiconductor base 10, while the second portion 29-R of the embedded film 29 is provided between the second projected portion 31c-R of the head part 31a of the gate electrode 31 and the semiconductor base 10.

Further, the head part 31a of the gate electrode 31 is located on the insulation layer 20. Accordingly, as depicted in FIGS. 3 and 4, a part of the first insulation film 21, a part of the second insulation film 22, and a part of the third insulation film 25 are also provided between the head part 31a of the gate electrode 31 and the semiconductor base 10.

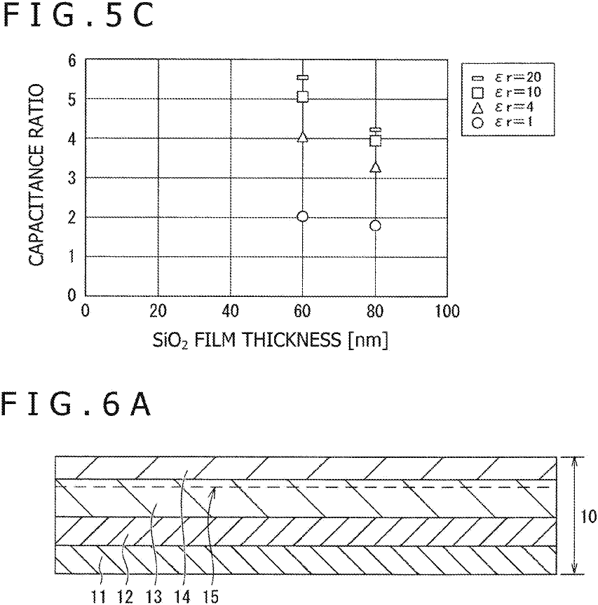

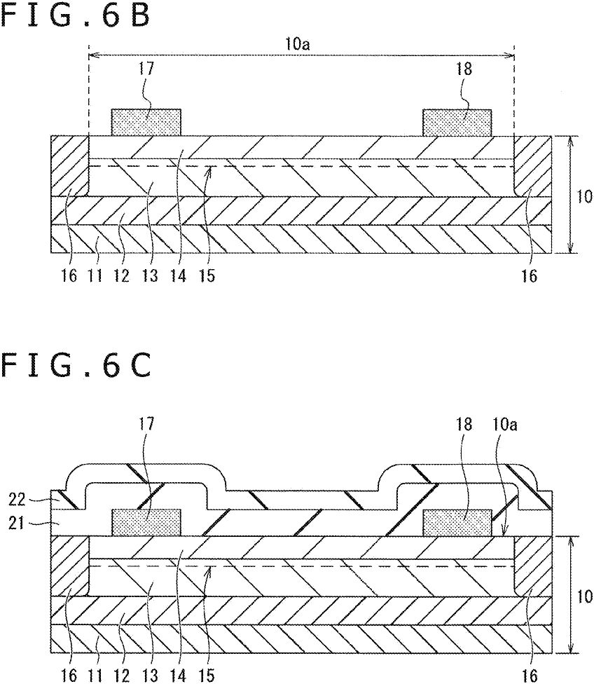

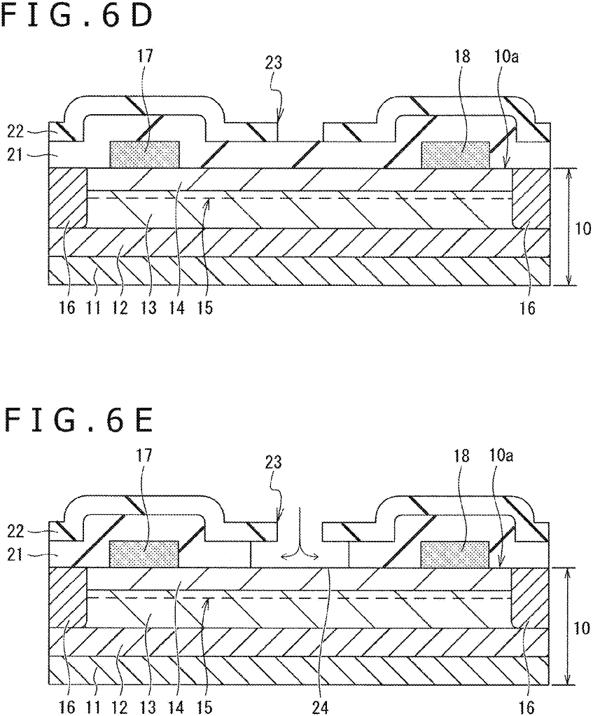

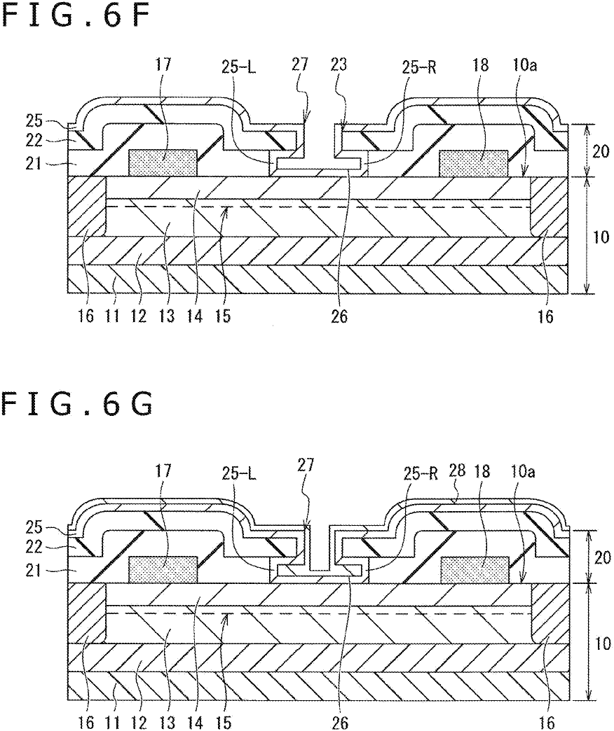

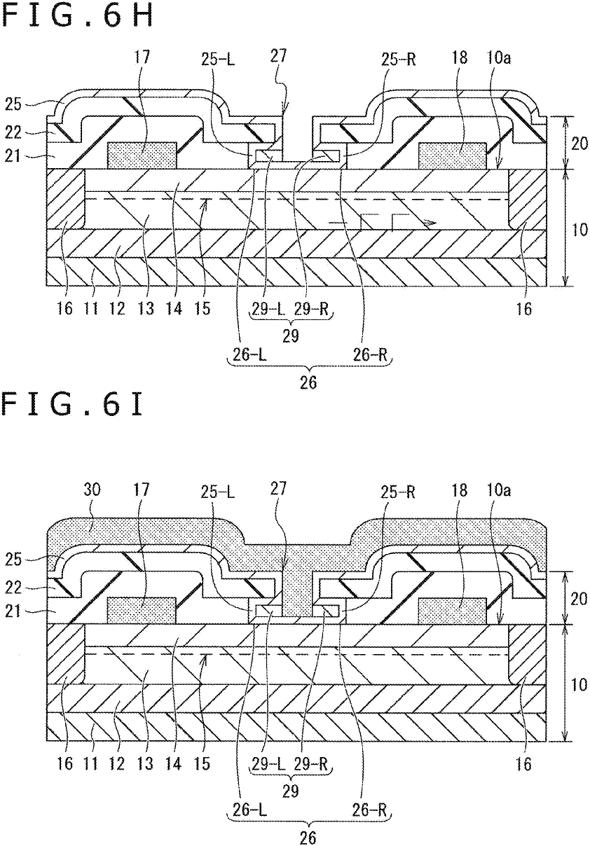

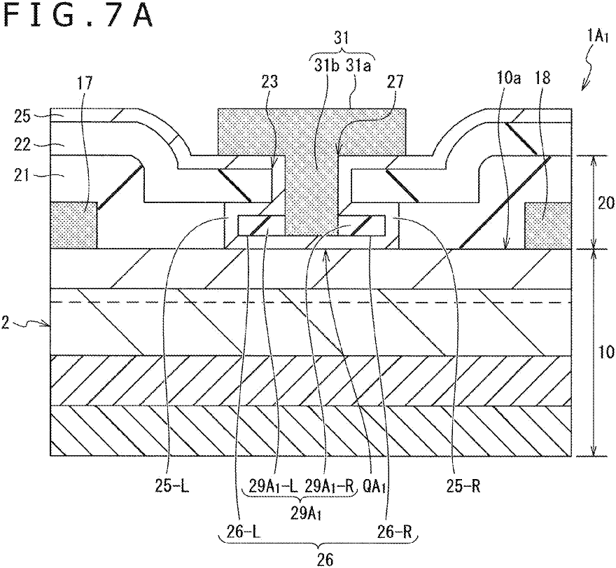

Here, the width of the body part 31b of the gate electrode 31 is defined by the width of the gate opening 27 in the gate length direction. In addition, the width of the gate opening 27 in the gate length direction is defined by the width of an opening 23 in the gate length direction depicted in FIG. 6D. Moreover, the opening 23 is formed by selectively removing a part of the second insulation film 22 by dry etching. Further, the chamber 26 is formed by selectively removing a part of the first insulation film 21 by wet etching.

As depicted in FIG. 4, an end 29a of the embedded film 29 in the gate length direction is one of two opposite ends of the embedded film 29 in the gate length direction and corresponds to an end located away from the body part 31b. In addition, there are provided, as the end 29a, an end 29a-L of the first portion 29-L of the embedded film 29 and an end 29a-R of the second portion 29-R of the embedded film 29.

As depicted in FIG. 4, each of the first projected portion 31c-L and the second projected portion 31c-R of the gate electrode 31 has a projection amount La from the body part 31b.

Assuming that a position of a projection start of the first projected portion 31c-L of the gate electrode 31 from the body part 31b is a reference position, the position of the end 29a-L of the embedded film 29 in the gate length direction corresponds to a position away from the gate electrode 31 by an amount of 80% of the projection amount La. Similarly, assuming that a position of a projection start of the second projected portion 31c-R of the gate electrode 31 from the body part 31b is a reference position, the position of the end 29a-R of the embedded film 29 in the gate length direction corresponds to a position away from the gate electrode 31 by an amount of 80% of the projection amount La. In other words, the contour of the embedded film 29 in the plan view is located at a position corresponding to 80% of the projection amount of the projected portion of the gate electrode 31.

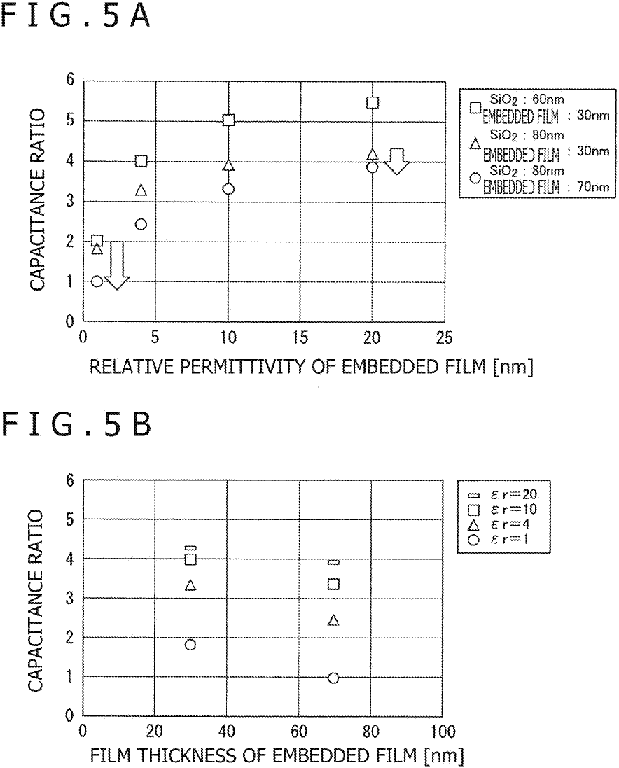

Here, for reducing damage to the semiconductor base 10 by dry etching, the thickness of the first insulation film 21 is desired to be increased. In this case, however, the thickness of the chamber 26 produced by withdrawal of the first insulation film 21 also becomes large. Accordingly, the thickness of the embedded film 29 embedded in the chamber 26 similarly becomes large. As depicted in FIGS. 5A to 5C, the thickness of the chamber 26 and the relative permittivity inside the chamber 26 influence capacitance of the gate electrode 31, and therefore influence a field plate effect.

The relative permittivity of the embedded film 29 will hereinafter be described with reference to FIGS. 5A, 5B, and 5C. In FIG. 5A, a horizontal axis represents a relative permittivity of the embedded film 29, while a vertical axis represents a capacitance ratio of the gate electrode 31. In addition, it is assumed in FIG. 5A that the first insulation film 21 includes an aluminum oxide film, and that the second insulation film 22 includes a silicon oxide film. Each plot represented by a circle indicates a case where the thickness of the silicon oxide film and the thickness of the embedded film 29 are 80 nm and 70 nm, respectively. Each plot represented by a triangle indicates a case where the thickness of the silicon oxide film and the thickness of the embedded film 29 are 80 nm and 30 nm, respectively. Each plot represented by a square indicates a case where the thickness of the silicon oxide film and the thickness of the embedded film 29 are 60 nm and 30 nm, respectively.

The capacitance here refers to combined capacitance in the longitudinal direction between the head part 31a of the gate electrode 31 and the main surface of the semiconductor base 10. FIG. 5A presents capacitance ratios in a case where combined capacitance is set to 1 (reference) in such a situation that the embedded film 29 has a film thickness of 70 nm and a relative permittivity of 1 (permittivity of vacuum), and that the silicon oxide film has a film thickness of 80 nm.

A first plot group from the left in FIG. 5A represents capacitance ratios in a case where the relative permittivity of the embedded film 29 is set to 1, i.e., the permittivity of a vacuum. A state where the relative permittivity of the embedded film 29 is the same as the permittivity of a vacuum is considered to be the same as a state where the inside of the chamber 26 is in a vacuum condition.

A second plot group from the left represents capacitance ratios in a case where the relative permittivity of the embedded film 29 is the same as the relative permittivity of the silicon oxide film, i.e., the second insulation film 22.

A third plot group from the left represents capacitance ratios in a case where the relative permittivity of the embedded film 29 is the same as the relative permittivity of the aluminum oxide film, i.e., the first insulation film 21.

Moreover, a fourth plot group from the left represents capacitance ratios in a case where the relative permittivity of the embedded film 29 is higher than the relative permittivity of the aluminum oxide film, i.e., the first insulation film 21.

The combined capacitance increases, i.e., the field plate effect increases, as the relative permittivity of the embedded film 29 is raised from 1 corresponding to the vacuum (the first plot group from the left). Moreover, as can be seen, in a case where the film thickness of the embedded film 29 is changed from 30 nm (triangle plot) to 70 nm (circle plot) to avoid dry etching damage to the main surface of the semiconductor base 10 or the gate insulation film, the combined capacitance considerably decreases when the relative permittivity of the embedded film 29 is lower than the relative permittivity of the silicon oxide film (the second plot group from the left) (the difference between the triangle plot and the circle plot is large). However, this capacitance decrease is reduced (the difference between the triangle plot and the circle plot becomes smaller) as the relative permittivity of the embedded film 29 becomes higher than the relative permittivity of the silicon oxide film. In this case, sensitivity of the thickness of the silicon oxide film to the combined capacitance increases. Moreover, when the difference between the triangle plot and the circle plot decreases, the capacitance ratio can be raised even by the embedded film 29 having a large thickness. In addition, the field plate effect increases as the capacitance ratio increases.

FIG. 5B presents film thickness dependency of the embedded film 29 (relative permittivity difference of the embedded film 29) concerning the combined capacitance when the film thickness of the silicon oxide film is fixed to 80 nm, while FIG. 5C presents film thickness dependency of the silicon oxide film (second insulation film 22) (relative permittivity difference of the embedded film 29) concerning the combined capacitance when the film thickness of the embedded film 29 is fixed to 30 nm. Each plot represented by a circle indicates a case where the relative permittivity of the embedded film 29 is 1. Each plot represented by a triangle indicates a case where the relative permittivity of the embedded film 29 is 4. Each plot represented by a square indicates a case where the relative permittivity of the embedded film 29 is 10. Each plot represented by a rectangle indicates a case where the relative permittivity of the embedded film 29 is “20.”

It is obvious from FIGS. 5B and 5C that sensitivity of each film thickness to the combined capacitance varies according to the relative permittivity of the embedded film 29. Specifically, even when the thickness of the embedded film 29, i.e., the first insulation film 21, is increased to avoid surface damage to the semiconductor base 10, the combined capacitance is considered to be raised (the field plate effect can be improved) by increasing the film thickness of the silicon oxide film (second insulation film 22).

In this manner, the field plate effect increases by setting the relative permittivity of the embedded film 29 to a value equal to or higher than the relative permittivity of the second insulation film 22. Moreover, the capacitance ratio can be raised by setting the relative permittivity of the embedded film 29 to a value higher than the relative permittivity of the second insulation film 22 even when the thickness of the first insulation film 21 is increased to avoid the surface damage of the semiconductor base 10. As a result, the field plate effect improves.

As depicted in FIG. 3, the gate electrode 31 is provided on the third insulation film 25. In other words, the gate electrode 31 is formed in a layer above the third insulation film 25. For example, the gate electrode 31 includes laminated films of a nickel (Ni) film and a gold (Au) film sequentially laminated from the semiconductor base 10 side.

The pair of main electrodes 17 and 18 are joined to the barrier layer 14 by ohmic junction in the active region 10a. The pair of main electrodes 17 and 18 each include laminated films of a titanium (Ti) film, an Al film, an Ni film, and an Au film sequentially laminated from the semiconductor base 10 side, for example.

In a case where the field effect transistor QA is of a depression type which designates a negative voltage as a threshold voltage, for example, the number of carriers in a carrier depleted region included in a surface portion of the channel layer 13 immediately below the gate electrode 31 decreases when a gate voltage Vg is applied to the gate electrode 31. In this case, the number of electrons in the channel layer 13 decreases, and therefore substantially no drain current Id flows. In addition, when a positive gate voltage Vg is applied to the gate electrode 31, the carrier depleted region disappears. In this case, the number of electrons in the buffer layer 12 increases, and the drain current Id is modulated.

As apparent from above, according to the semiconductor device 1A of the first embodiment, fluctuation of characteristics and deterioration of characteristics of the field effect transistor QA, i.e., fluctuation of characteristics and deterioration of characteristics of the semiconductor device 1A, can be reduced while damage to the main surface of the semiconductor base 10 is lowered.

Moreover, according to the semiconductor device 1A of the first embodiment, the embedded film 29 as an insulation film is provided on the side of the gate electrode 31. Accordingly, capacitance between the head part 31a of the gate electrode 31 and the main surface of the semiconductor base 10 can improve. In addition, with improvement of the capacitance, the field plate effect also improves. Accordingly, concentration of the electric field on the main surface of the semiconductor base 10 can further be relieved. As a result, fluctuation of characteristics and deterioration of characteristics, such as a drain-lag and Vth fluctuation, can be reduced.

Further, according to the semiconductor device 1A of the first embodiment, each thickness of the embedded film 29 and the first insulation film 21 can be increased by raising the permittivity of the embedded film 29. Accordingly, not only relief of the electric field, but also avoidance of damage to the semiconductor surface and the gate insulation film by dry etching during gate opening is achievable. As a result, fluctuation of characteristics can be reduced by improvement of the interface condition.

In addition, according to the semiconductor device 1A of the first embodiment, the embedded film 29 is provided between the head part 31a of the gate electrode 31 and the semiconductor base 10. Accordingly, the capacitance between the head part 31a of the gate electrode 31 and the main surface of the semiconductor base 10 can be improved without increasing the permittivity of the entire first insulation film 21. Moreover, the portion having a high permittivity is only the portion below the head part 31a of the gate electrode 31. Accordingly, the increase in the capacitance is controllable by the width, the thickness, and the permittivity of the embedded film 29 corresponding to the high permittivity region.

Note that the projected portions 31c include both the first projected portion 31c-L located on one side surface side of the body part 31b (left side), and the second projected portion 31c-R located on the other side surface side of the body part 31b (right side). However, the projected portions 31c may include at least any one of the first and second projected portions 31c-L and 31c-R.

Note that a wiring layer and other insulation layers are provided as layers above the insulation layer 20. However, the wiring layer and the other insulation layers as layers above the insulation layer 20 are not depicted in FIG. 3.

### <<Manufacturing Method of Semiconductor Device>>

A manufacturing method of the semiconductor device 1A will subsequently be described with reference to FIGS. 6A to 6I.

Initially, as depicted in FIG. 6A, the semiconductor base 10 is prepared. The semiconductor base 10 has a laminated structure where the buffer layer 12, the channel layer 13, and the barrier layer 14 are laminated in this order on the substrate 11. In addition, the two-dimensional electron gas layer 15 is provided in the vicinity of the junction interface between the channel layer 13 and the barrier layer 14.

Subsequently, as depicted in FIG. 6B, the non-active region 16 for sectioning and insulating the active region 10a is formed in the main surface of the semiconductor base 10. In addition, the pair of main electrodes 17 and 18 functioning as a source electrode and a drain electrode are formed on the active region 10a of the main surface of the semiconductor base 10.

The non-active region 16 can be formed by selectively implanting boron (B⁺) ions or the like as impurity ions into the surface portion on the main surface side of the semiconductor base 10, and then conducting heat treatment for activating the implanted B⁺ ions.

The pair of main electrodes 17 and 18 can be formed by sequentially accumulating a Ti film, an Al film, an Ni film, and an Au film, for example, on the entire main surface of the semiconductor base 10 including the active region 10a from the semiconductor base 10 side by CVD or sputtering to form a conductive film having a multilayer structure, and then by patterning this conductive film with use of a known photolithography technology and a dry etching technology having high directivity. The pair of main electrodes 17 and 18 each have a long shape, and are disposed away from each other in a short direction (width direction) crossing a long direction at right angles.

Subsequently, as depicted in FIG. 6C, the first insulation film 21 is formed on the entire main surface of the semiconductor base 10 including the active region 10a. Thereafter, as depicted in FIG. 6C, the second insulation film 22 is formed on the entire main surface of the semiconductor base 10 including the active region 10a with the first insulation film 21 interposed between the second insulation film 22 and the main surface of the semiconductor base 10. The second insulation film 22 is formed by an insulation film having etching selectivity higher than etching selectivity of the first insulation film 21. For example, an aluminum oxide (Al₂O₃) film is formed as the first insulation film 21 through ALD (Atomic Layer Deposition), and a silicon oxide (SiO₂) film is formed as the second insulation film 22 through the CVD (Chemical Vapor Deposition).

By this step, the active region 10a of the main surface of the semiconductor base 10 is covered with the first insulation film 21 and the second insulation film 22.

Subsequently, as depicted in FIG. 6D, the opening 23 is formed in the second insulation film 22 on the active region 10a of the main surface of the semiconductor base 10. The opening 23 is formed by selectively etching the second insulation film 22 with use of a known photolithography technology and known dry etching having high directivity as an anisotropic etching technology.

The opening 23 is formed between the pair of main electrodes 17 and 18 in the plan view, and formed in a long-shaped planar pattern extending in the long direction of the pair of main electrodes 17 and 18. The width of the opening 23 formed herein in the gate length direction defines the width of the gate opening 27 in the gate length direction as an opening formed in a step described below (FIG. 6F). In addition, this width of the gate opening 27 in the gate length direction defines the width of the gate electrode 31 in the gate length direction as a gate electrode formed in a step described below.

Subsequently, as depicted in FIG. 6E, a chamber 24 having a larger width than the opening 23 is formed by etching the first insulation film 21 on the active region 10a of the semiconductor base 10 with use of the opening 23.

Etching of the first insulation film 21 is achieved by isotropic wet etching which gives less damage to the main surface of the semiconductor base 10, i.e., the surface of the barrier layer 14. At this time, the chamber 24 is formed by side etching applied to the first insulation film 21. The wet etching of the first insulation film 21 is performed under such a condition that etching selectivity of the first insulation film 21 is securable for the second insulation film 22. Specifically, wet etching of the first insulation film 21 is performed under such a condition of a higher wet etching rate than that of the second insulation film 22. Higher selectivity is more preferable. For example, etching is performed under such a condition that the ratio of the etching selectivity of the first insulation film 21 to the etching selectivity of the second insulation film 22 is set to 10 or more to 1.

Subsequently, formed as depicted in FIG. 6F is the third insulation film 25 which covers the first insulation film 21, the second insulation film 22, and the main surface of the semiconductor base 10 (the surface of the barrier layer 14) within the chamber 24, and also covers respective side walls inside the opening 23 of the second insulation film 22 and the upper part of the second insulation film 22. For example, the third insulation film 25 is formed by forming an AL₂O₃ film, an HfO₂ film, or the like by use of the ALD. The ALD is capable of forming a homogeneous film. Accordingly, the exposed surfaces of the barrier layer 14, the first insulation film 21, and the second insulation film 22 are covered with the homogeneous third insulation film 25.

In this step, the insulation layer 20 including the first insulation film 21, the second insulation film 22, and the third insulation film 25 is formed on the active region 10a of the semiconductor base 10. In this case, the upper part of the active region 10a of the semiconductor base 10 including the pair of main electrodes 17 and 18 is covered with the insulation layer 20.

Moreover, the chamber 26 which has the inner surface covered with the third insulation film 25 is formed in this step.

Further, the respective side walls of the opening 23 in the second insulation film 22 are covered with the third insulation film 25 in this step. Accordingly, the gate opening 27 which has an opening width smaller than the width of the opening 23 is formed. The width of the gate opening 27 in the gate length direction defines the width of the gate electrode 31 in the gate length direction as a gate electrode formed in a step described below.

Subsequently, as depicted in FIG. 6G, an embedded material 28 covering the upper part of the third insulation film 25 is formed. The embedded material 28 is accumulated on all surfaces such as the upper surface, the lower surface, and the side surface within the chamber 26. Accordingly, as depicted in FIG. 6G, the inside of the chamber 26 including the inside of the first portion 26-L and the second portion 26-R is filled with the embedded material 28. For example, the embedded material 28 is formed through the ALD. For example, a single layer film which is any one of a zirconium oxide (ZrO₂) film, a lanthanum oxide (La₂O₃) film, and an yttrium oxide (Y₂O₃) film or a laminated film containing at least any two of these films is formed through the ALD to constitute the embedded material 28.

Subsequently, as depicted in FIG. 6H, the embedded material 28 other than a portion forming the embedded film 29 is removed by a known photolithography technology and isotropic wet etching which gives less damage to the main surface of the semiconductor base 10, i.e., the surface of the barrier layer 14. Wet etching of the embedded material 28 is performed under such a condition that etching selectivity of the embedded material 28 is securable for the third insulation film 25. Specifically, wet etching of the embedded material 28 is performed under such a condition of a higher wet etching rate than that of the third insulation film 25. Higher selectivity is more preferable. For example, etching is performed under such a condition that the ratio of the etching selectivity of the embedded material 28 to the etching selectivity of the third insulation film 25 is set to 10 or more to 1.

In the manner described above, the inside of the first portion 26-L and the second portion 26-R of the chamber 26 is selectively filled with the embedded material 28 to constitute the embedded film 29.

Note that the side surface of the embedded film 29 on the gate opening 27 side is flush with the inner wall surface of the gate opening 27 in FIG. 6H. However, the side surface of the embedded film 29 on the gate opening 27 side may be withdrawn to the outside (first insulation film 21 side) of the inner wall surface of the gate opening 27 by an effect of side etching during selective removal of the embedded material 28.

Subsequently, as depicted in FIG. 6I, a gate material 30 is formed on the entire surface of the third insulation film 25 including the active region 10a of the semiconductor base 10. For example, the gate material 30 is formed by sequentially accumulating an Ni film and an Au film by deposition from the semiconductor base 10 side.

In this step, the inside of the gate opening 27 is filled with the gate material 30, and also the portion immediately below the gate opening 27 within the chamber 26 is selectively filled with the gate material 30. Thereafter, the gate material 30 is patterned with use of a known photolithography technology and a dry etching technology having high directivity to form the gate electrode 31 on the active region 10a of the semiconductor base 10. In this manner, the gate electrode 31 depicted in FIG. 3 is formed.

Note that the gate electrode 31 may be formed by lift-off.

In this step, the gate electrode 31 is formed into such a gate electrode which has the head part 31a located on the insulation layer 20, and the body part 31b penetrating from the head part 31a through the insulation layer 20, protruding to the chamber 26, and further extending toward the main surface of the semiconductor base 10, and also is shaped such that the head part 31a has a larger width than the width of the body part 31b.

By this step, manufacture of the field effect transistor QA depicted in FIGS. 2 and 3 is substantially completed.

Thereafter, the wiring layer and the other insulation layers are formed on the insulation layer 20. As a result, manufacture of the semiconductor device 1A depicted in FIGS. 1 to 3 is substantially completed.

According to the manufacturing method of the semiconductor device 1A of the first embodiment, the first insulation film 21 is etched by wet etching. Accordingly, damage to the main surface of the semiconductor base 10 (barrier layer 14) can be reduced. Specifically, exposure of the main surface of the semiconductor base 10 to plasma during etching, and entrance of ions or the like contained in etching gas into the semiconductor base 10 are prevented. Accordingly, deterioration of on-resistance, i.e., an increase in sheet resistance, and deterioration of off-characteristics, i.e., an increase in leak current and lowering of breakdown voltage, are not caused.

In addition, according to the manufacturing method of the semiconductor device 1A of the first embodiment, the embedded film 29 is formed inside the chamber 26 produced by side etching of the first insulation film 21 with use of wet etching described above. Accordingly, capacitance between the head part 31a of the gate electrode 31 and the main surface of the semiconductor base 10 can be improved. According to the improvement of the capacitance, the field plate effect improves, and concentration of the electric field on the main surface of the semiconductor base 10 can further be relieved. As a result, fluctuation of characteristics and deterioration of characteristics, such as a drain-lag and Vth fluctuation, can be reduced.

Further, according to the manufacturing method of the semiconductor device 1A of the first embodiment, each thickness of the embedded film 29 and the first insulation film 21 can be increased by raising the permittivity of the embedded material 28 constituting the embedded film 29. Accordingly, not only relief of the electric field, but also avoidance of damage to the semiconductor surface and the gate insulation film by dry etching during gate opening is achievable. As a result, fluctuation of characteristics can be reduced by improvement of the interface condition.

In addition, according to the manufacturing method of the semiconductor device 1A of the first embodiment, the third insulation film 25 is formed after formation of the opening 23 is completed. Accordingly, damage to the third insulation film 25 during dry etching can be reduced.

Note that the side surface of the embedded film 29 on the gate opening 27 side (the body part 31b side of the gate electrode 31) is substantially flush with the inner wall surface of the gate opening 27 in FIGS. 3 and 4. However, as described above, in a case where the side surface of the embedded film 29 on the gate opening 27 side is withdrawn to the outside (first insulation film 21 side) of the inner wall surface of the gate opening 27 due to the effect of side etching during selective removal of the embedded material 28, a space portion may be formed between the body part 31b of the gate electrode 31 and the embedded film 29.

### First Modification of First Embodiment

### <<Configuration of Semiconductor Device>>

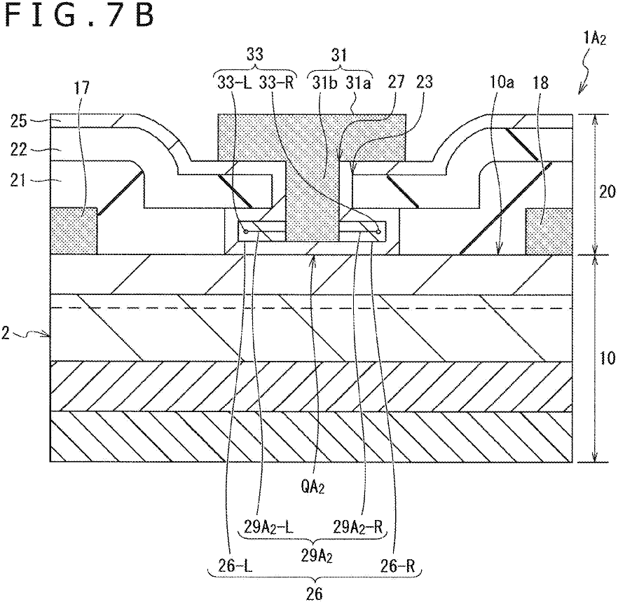

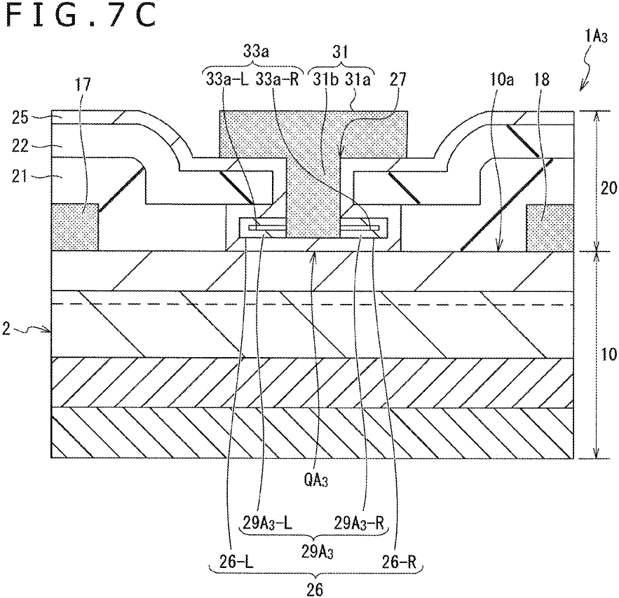

As depicted in FIG. 7A, a semiconductor device 1A₁ according to a first modification of the first embodiment of the present technology basically has a configuration similar to the configuration of the semiconductor device 1A of the first embodiment described above, and includes a field effect transistor QA₁ instead of the field effect transistor QA of the first embodiment.

As depicted in FIG. 7A, the field effect transistor QA₁ includes an embedded film 29A₁ instead of the embedded film 29 of the first embodiment depicted in FIG. 3. The embedded film 29 according to the first embodiment described above includes a material different from the material of the first insulation film 21. However, the embedded film 29A₁ according to the first modification of the first embodiment includes the same material as the material of the first insulation film 21. Accordingly, the embedded film 29A₁ has the same relative permittivity as the relative permittivity of the first insulation film 21. Other configurations of the field effect transistor QA₁ are substantially similar to the corresponding configurations of the field effect transistor QA of the first embodiment described above.

For example, in a case where the first insulation film 21 includes an aluminum oxide (Al₃O₂) film, the embedded film 29A₁ includes an aluminum oxide film. The relative permittivity of the embedded film 29A₁ is the relative permittivity of the aluminum oxide film.

As depicted in FIG. 7A, the embedded film 29A₁ includes a first portion 29A₁-L located on one side surface side of the body part 31b (left side in FIG. 7A), and a second portion 29A₁-R located on the other side surface side of the body part 31b (right side in FIG. 7A) in the gate length direction of the gate electrode 31. The first portion 29A₁-L of the embedded film 29A₁ fills the first portion 26-L of the chamber 26, while the second portion 29A₁-R of the embedded film 29A₁ fills the second portion 26-R of the chamber 26.

In addition, as in the first embodiment, the embedded film 29A₁ and the first insulation film 21 are separated from each other by the third insulation film 25.

The semiconductor device 1A₁ according to the first modification of the first embodiment also offers advantageous effects similar to those of the semiconductor device 1A of the first embodiment described above.

Further, according to the semiconductor device 1A₁ of the first embodiment, each thickness of the embedded film 29A₁ and the first insulation film 21 can be increased by equalizing the relative permittivity of the embedded film 29A₁ with the relative permittivity of the first insulation film 21. Accordingly, not only relief of the electric field, but also avoidance of damage to the semiconductor surface and the gate insulation film by dry etching during gate opening is achievable. As a result, fluctuation of characteristics can be reduced by improvement of the interface condition.

### <<Manufacturing Method of Semiconductor Device>>

A manufacturing method of the semiconductor device 1A₁ according to the first modification of the first embodiment will subsequently be described. The manufacturing method of the semiconductor device 1A₁ according to the first modification of the first embodiment is the same as the manufacturing method of the semiconductor device 1A of the first embodiment depicted in FIGS. 6A to 6I except that the material forming the embedded material 28 is the same as the material of the first insulation film 21, such as an aluminum oxide film.

The manufacturing method of the semiconductor device 1A₁ according to the first modification of the first embodiment also offers advantageous effects similar to those of the manufacturing method of the semiconductor device 1A of the first embodiment described above.

Further, according to the manufacturing method of the semiconductor device 1A₁ of the first modification of the first embodiment, each thickness of the embedded film 29A₁ and the first insulation film 21 can be increased by equalizing the material of the embedded material 28 constituting the embedded film 29A₁ with the material of the first insulation film 21 and thereby raising the relative permittivity of the embedded film 29A₁. Accordingly, not only relief of the electric field, but also avoidance of damage to the semiconductor surface and the gate insulation film by dry etching during gate opening is achievable. As a result, fluctuation of characteristics can be reduced by improvement of the interface condition.

Note that the side surface of the embedded film 29A₁ on the gate opening 27 side (the body part 31b side of the gate electrode 31) is also substantially flush with the inner wall surface of the gate opening 27 in the first modification of the first embodiment as depicted in FIG. 7A. However, as in the first embodiment described above, a space portion may be formed between the body part 31b of the gate electrode 31 and the embedded film 29A₁.

### Second Modification of First Embodiment

As depicted in FIG. 7B, a semiconductor device 1A₂ according to a second modification of the first embodiment of the present technology basically has a configuration similar to the configuration of the semiconductor device 1A of the first embodiment described above, and includes a field effect transistor QA₂ instead of the field effect transistor QA of the first embodiment.

As depicted in FIG. 7B, the field effect transistor QA₂ includes an embedded film 29A₂ instead of the embedded film 29 of the first embodiment depicted in FIG. 3. Other configurations are substantially similar to the corresponding configurations of the field effect transistor QA of the first embodiment described above and depicted in FIG. 3.

As depicted in FIG. 7B, the embedded film 29A₂ includes a first portion 29A₂-L located on one side surface side of the body part 31b (left side), and a second portion 29A₂-R located on the other side surface side of the body part 31b (right side) in the gate length direction of the gate electrode 31. The field effect transistor QA₂ includes space portions 33.

As depicted in FIG. 7B, the embedded film 29A₂ has the space portions 33 inside the embedded film 29A₂. The space portions 33 are formed in a case where the chamber 26 is not completely filled with the embedded film 29A₂. The space portions 33 include a first portion 33-L formed in the first portion 29A₂-L of the embedded film 29A₂, and a second portion 33-R formed in the second portion 29A₂-R of the embedded film 29A₂.

Note that the first modification of the first embodiment described above may be applied to the semiconductor device 1A₂ of the second modification of the first embodiment.

The semiconductor device 1A₂ according to the second modification of the first embodiment also offers advantageous effects similar to those of the semiconductor device 1A of the first embodiment described above.

Moreover, the manufacturing method of the semiconductor device 1A₂ according to the second modification of the first embodiment also offers advantageous effects similar to those of the manufacturing method of the semiconductor device 1A of the first embodiment described above.

Note that the side surface of the embedded film 29A₂ on the gate opening 27 side (the body part 31b side of the gate electrode 31) is also substantially flush with the inner wall surface of the gate opening 27 in the second modification of the first embodiment as depicted in FIG. 7B. However, as in the first embodiment described above, a space portion may be formed between the body part 31b of the gate electrode 31 and the embedded film 29A₂.

### Third Modification of First Embodiment

As depicted in FIG. 7C, a semiconductor device 1A₃ according to a third modification of the first embodiment of the present technology basically has a configuration similar to the configuration of the semiconductor device 1A of the first embodiment described above, and includes a field effect transistor QA₃ instead of the field effect transistor QA of the first embodiment.

As depicted in FIG. 7C, the field effect transistor QA₃ includes an embedded film 29A₃ instead of the embedded film 29 of the field effect transistor QA of the first embodiment described above and depicted in FIG. 3. Other configurations are substantially similar to the corresponding configurations of the field effect transistor QA of the first embodiment described above. The embedded film 29A₃ includes a first portion 29A₃-L located on one side surface side of the body part 31b (left side), and a second portion 29A₃-R located on the other side surface side of the body part 31b (right side) in the gate length direction of the gate electrode 31.

As depicted in FIG. 7C, the field effect transistor QA₃ includes space portions 33a. The space portions 33a are formed in a case where the chamber 26 is not completely filled with the embedded film 29A₃. The space portions 33a include a first portion 33a-L formed in the first portion 29A₃-L of the embedded film 29A₃, and a second portion 33a-R formed in the second portion 29A₃-R of the embedded film 29A₃.

Note that the first modification of the first embodiment described above may be applied to the semiconductor device 1A₃ of the third modification of the first embodiment.

The semiconductor device 1A₃ according to the third modification of the first embodiment also offers advantageous effects similar to those of the semiconductor device 1A of the first embodiment described above.

Moreover, the manufacturing method of the semiconductor device 1A₃ according to the third modification of the first embodiment also offers advantageous effects similar to those of the manufacturing method of the semiconductor device 1A of the first embodiment described above.

Note that the side surface of the embedded film 29A₃ on the gate opening 27 side (the body part 31b side of the gate electrode 31) is also substantially flush with the inner wall surface of the gate opening 27 in the third modification of the first embodiment as depicted in FIG. 7C. However, as in the first embodiment described above, a space portion may be formed between the body part 31b of the gate electrode 31 and the embedded film 29A₃. In this case, the space portion formed between the body part 31b of the gate electrode 31 and the embedded film 29A₃ may communicate with the hollow portions 33a.

### Second Embodiment

### <<Configuration of Semiconductor Device>>

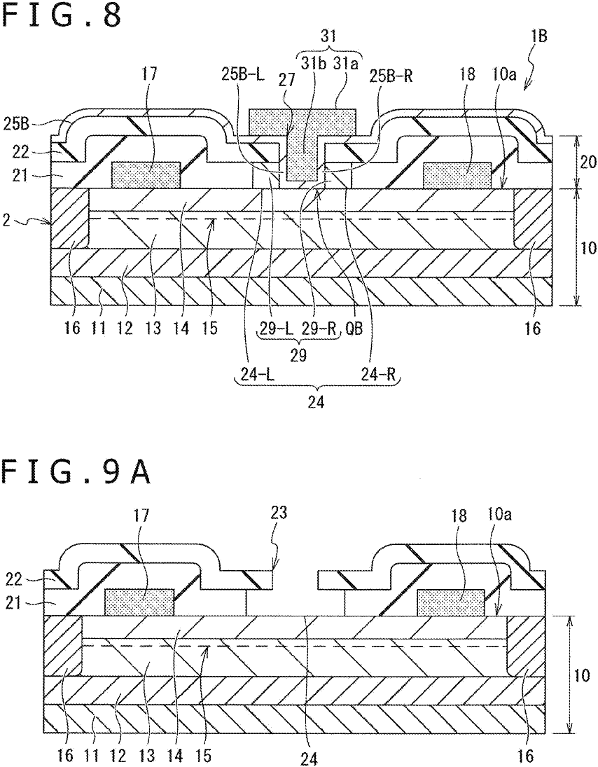

As depicted in FIG. 8, a semiconductor device 1B according to a second embodiment of the present technology basically has a configuration similar to the configuration of the semiconductor device 1A of the first embodiment described above, and includes a field effect transistor QB instead of the field effect transistor QA of the first embodiment.

As depicted in FIG. 8, the field effect transistor QB includes the embedded film 29 filling the chamber 24. The chamber 24 includes a first portion 24-L located on one side surface side of the body part 31b (left side in FIG. 8), and a second portion 24-R located on the other side surface side of the body part 31b (right side) in the gate length direction of the gate electrode 31. The inner surface of the chamber 24 is not covered with a third insulation film 25B unlike in the first embodiment described above.

As depicted in FIG. 8, the embedded film 29 includes the first portion 29-L located on one side surface side of the body part 31b (left side), and the second portion 29-R located on the other side surface side of the body part 31b (right side) in the gate length direction of the gate electrode 31. The first portion 29-L of the embedded film 29 fills the first portion 24-L of the chamber 24, while the second portion 29-R of the embedded film 29 fills the second portion 24-R of the chamber 24.

As depicted in FIG. 8, the third insulation film 25B is provided between the embedded film 29 and the body part 31b of the gate electrode 31. The third insulation film 25B includes a first portion 25B-L and a second portion 25B-R. The first portion 25B-L of the third insulation film 25B is provided between the first portion 29-L of the embedded film 29 and the body part 31b, while the second portion 25B-R of the third insulation film 25B is provided between the second portion 29-R of the embedded film 29 and the body part 31b. In this manner, the embedded film 29 and the body part 31b are separated from each other by the third insulation film 25B.

The semiconductor device 1B according to the second embodiment also offers advantageous effects similar to those of the semiconductor device 1A of the first embodiment described above.

Note that at least any one of the first modification, the second modification, and the third modification of the first embodiment described above is applicable to the semiconductor device 1B of the second embodiment.

### <<Manufacturing Method of Semiconductor Device>>

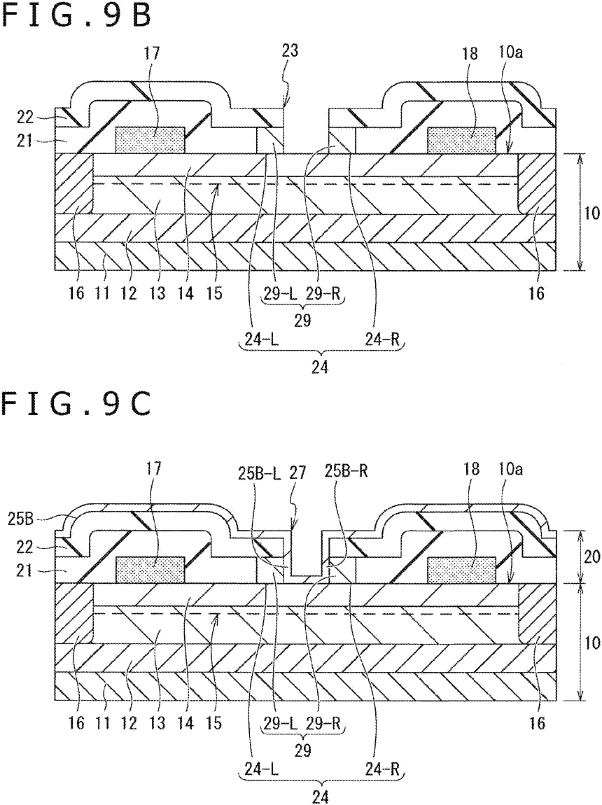

A manufacturing method of the semiconductor device 1B according to the second embodiment will subsequently be described with reference to FIGS. 9A to 9C.

Initially, steps similar to the steps depicted in FIGS. 6A to 6D of the first embodiment are performed to form the pair of main electrodes 17 and 18, the first and second insulation films 21 and 22, the opening 23, and others as depicted in FIG. 9A. Subsequently, a step similar to the step depicted in FIG. 6E of the first embodiment described above is performed to form the chamber 24 having a width larger than the width of the opening 23, and others as depicted in FIG. 9A.

Subsequently, steps similar to the steps depicted in FIGS. 6G and 6H of the first embodiment are performed to form the embedded film 29 as depicted in FIG. 9B.

Subsequently, as depicted in FIG. 9C, the third insulation film 25B covering the second insulation film 22, the embedded film 29, the main surface of the semiconductor base 10, and others is formed. The ALD is capable of forming a homogeneous film. Accordingly, the exposed surfaces of the barrier layer 14, the first insulation film 21, and the second insulation film 22 are covered with the homogeneous third insulation film 25B.

In this step, the insulation layer 20 including the first insulation film 21, the second insulation film 22, and the third insulation film 25B is formed on the active region 10a of the semiconductor base 10.

Further, the respective side walls of the opening 23 in the second insulation film 22 are covered with the third insulation film 25B in this step. Accordingly, the gate opening 27 which has an opening width smaller than that of the opening 23 is formed.

Thereafter, a step similar to the step depicted in FIG. 6I of the first embodiment is performed to form the gate electrode 31. In this manner, manufacture of the field effect transistor QB depicted in FIG. 8 is substantially completed.

The manufacturing method of the semiconductor device 1B according to the second embodiment also offers advantageous effects similar to those of the manufacturing method of the semiconductor device 1A of the first embodiment described above.

### Third Embodiment

### <<Configuration of Semiconductor Device>>

As depicted in FIG. 10, a semiconductor device 1C according to a third embodiment of the present technology basically has a configuration similar to the configuration of the semiconductor device 1A of the first embodiment described above, and includes a field effect transistor QC instead of the field effect transistor QA of the first embodiment.

As depicted in FIG. 10, the field effect transistor QC includes the embedded film 29 filling a chamber 26C. The chamber 26C is provided on a third insulation film 25C. Moreover, the chamber 26C includes a first portion 26C-L located on one side surface side of the body part 31b (left side), and a second portion 26C-R located on the other side surface side of the body part 31b (right side) in the gate length direction of the gate electrode 31.

As depicted in FIG. 10, the embedded film 29 includes the first portion 29-L located on one side surface side of the body part 31b (left side in FIG. 10), and the second portion 29-R located on the other side surface side of the body part 31b (right side in FIG. 10) in the gate length direction of the gate electrode 31. The first portion 29-L of the embedded film 29 fills the first portion 26C-L of the chamber 26C, while the second portion 29-R of the embedded film 29 fills the second portion 26C-R of the chamber 26C.

As depicted in FIG. 10, the third insulation film 25C is provided on the main surface of the semiconductor base 10. The third insulation film 25C includes a first portion 25C-L located on one side surface side of the body part 31b (left side in FIG. 10), and a second portion 25C-R located on the other side surface side of the body part 31b (right side in FIG. 10) in the gate length direction of the gate electrode 31.

The first portion 25C-L of the third insulation film 25C is provided between the main surface of the semiconductor base 10, and the first portion 29-L of the embedded film 29 and the first insulation film 21 adjacent to the first portion 29-L. Moreover, the second portion 25C-R of the third insulation film 25C is provided between the main surface of the semiconductor base 10, and the second portion 29-R of the embedded film 29 and the first insulation film 21 adjacent to the second portion 29-R. As described above, the third insulation film 25C is provided between the main surface of the semiconductor base 10, and the embedded film 29 and the first insulation film 21 adjacent to the embedded film 29.

Note that at least any one of the first modification, the second modification, and the third modification of the first embodiment described above may be applicable to the semiconductor device 1C of the third embodiment.

The semiconductor device 1C according to the third embodiment also offers advantageous effects similar to those of the semiconductor device 1A of the first embodiment described above.

### <<Manufacturing Method of Semiconductor Device>>

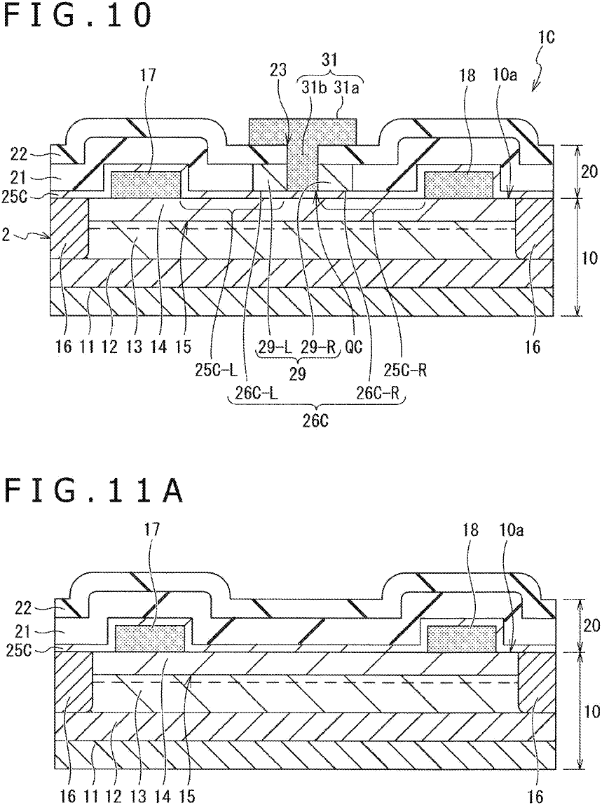

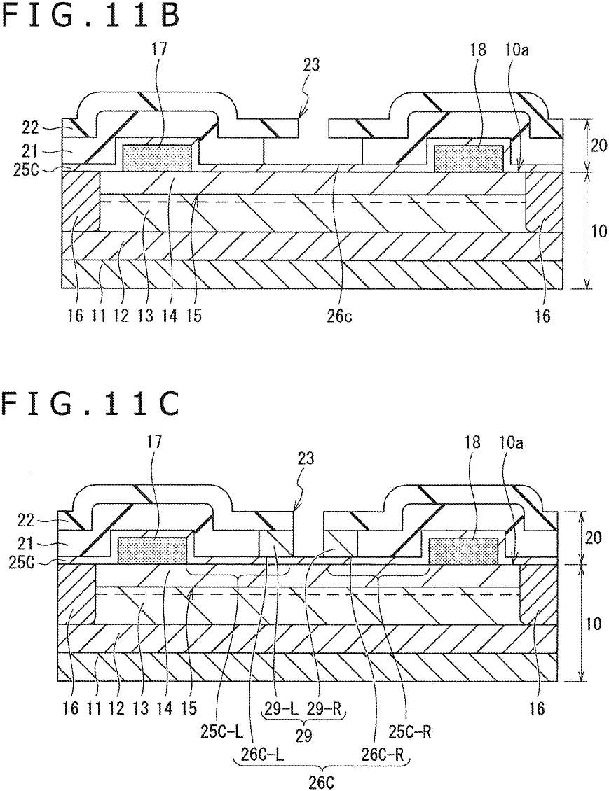

A manufacturing method of the semiconductor device 1C according to the third embodiment will subsequently be described with reference to FIGS. 11A to 11C.

First, as depicted in FIG. 11A, the semiconductor base 10 has a laminated structure where the buffer layer 12, the channel layer 13, the barrier layer 14, and the third insulation film 25C are laminated in this order on the substrate 11. In addition, the two-dimensional electron gas layer 15 is provided in the vicinity of the junction interface between the channel layer 13 and the barrier layer 14.

Subsequently, steps similar to the steps depicted in FIGS. 6B and 6C of the first embodiment are performed to form the pair of main electrodes 17 and 18, the first and second insulation films 21 and 22, and others, as depicted in FIG. 11A.

Subsequently, steps similar to the steps depicted in FIGS. 6D and 6E of the first embodiment are performed to form the opening 23, the chamber 26C having a width larger than the width of the opening 23, and others, as depicted in FIG. 11B. The chamber 26C is formed on the third insulation film 25C.

Subsequently, steps similar to the steps depicted in FIGS. 6G and 6H of the first embodiment are performed to form the embedded film 29, as depicted in FIG. 11C.

Thereafter, a step similar to the step depicted in FIG. 6I of the first embodiment is performed to form the gate electrode 31. In this manner, manufacture of the field effect transistor QC depicted in FIG. 10 is substantially completed.

The manufacturing method of the semiconductor device 1C according to the third embodiment also offers advantageous effects similar to those of the manufacturing method of the semiconductor device 1A of the first embodiment described above.

Note that the side surface of the embedded film 29 on the opening 23 side (the body part 31b side of the gate electrode 31) is also substantially flush with the inner wall surface of the opening 23, in the third embodiment, as depicted in FIG. 10. However, as in the first embodiment described above, a space portion may be formed between the body part 31b of the gate electrode 31 and the embedded film 29A.

### Fourth Embodiment

As depicted in FIG. 12, a semiconductor device 1D according to a fourth embodiment of the present technology basically has a configuration similar to the configuration of the semiconductor device 1B of the second embodiment described above, and includes a field effect transistor QD instead of the field effect transistor QB of the second embodiment.

As depicted in FIG. 12, the field effect transistor QD includes a gate electrode 31C instead of the gate electrode 31 of the field effect transistor QB depicted in FIG. 8. Other configurations are substantially similar to the corresponding configurations of the field effect transistor QB described above and depicted in FIG. 8.

As depicted in FIG. 12, the gate electrode 31C of the field effect transistor QD includes a head part 31Ca located on the insulation layer 20, and a body part 31Cb protruding from the head part 31Ca to the chamber 26 through the insulation layer 20 and extending toward the main surface of the semiconductor base 10.

The head part 31Da of the gate electrode 31D has a larger width than a width of the body part 31Db. The width of the body part 31Db of the gate electrode 31D in the gate length direction decreases from the head part 31Da toward the main surface of the semiconductor base 10. Specifically, the body part 31Db has an inverted tapered shape having two side surfaces which are located at positions opposite to each other in the gate length direction, and are inclined in such directions as to form an acute angle on the interior angle side by these two side surfaces and the main surface of the semiconductor base 10. Moreover, a distance between the gate electrode 31D including the head part 31Da and the body 31Db and the semiconductor base 10 decreases with nearness to the body part 31Db in the gate length direction of the gate electrode 31D. Further, capacitance between the gate electrode 31D and the semiconductor base 10 increases as the distance between the gate electrode 31D and the semiconductor base 10 decreases.

Note that the third insulation film 25B of the semiconductor device 1D according to the fourth embodiment basically has a configuration similar to the configuration of the third insulation film 25B of the second embodiment described above. However, the third insulation film 25B of the fourth embodiment may have a configuration similar to the configuration of the third insulation film 25 of the first embodiment described above, and of the third insulation film 25C of the third embodiment described above.

Moreover, at least any one of the first modification, the second modification, and the third modification of the first embodiment, and the third embodiment described above may be applicable to the semiconductor device 1D of the fourth embodiment.

The semiconductor device 1D according to the fourth embodiment also offers advantageous effects similar to those of the semiconductor device 1C of the first embodiment described above.

Further, according to the semiconductor device 1D of the fourth embodiment, the body part 31Db of the gate electrode 31D to be provided has an inverted tapered shape. In this case, the capacitance between the gate electrode 31D and the semiconductor base 10 increases with nearness to the body part 31Db of the gate electrode 31D in the gate length direction. Accordingly, relief of the electric field is promoted, and the field plate effect is enhanced.

### Fifth Embodiment

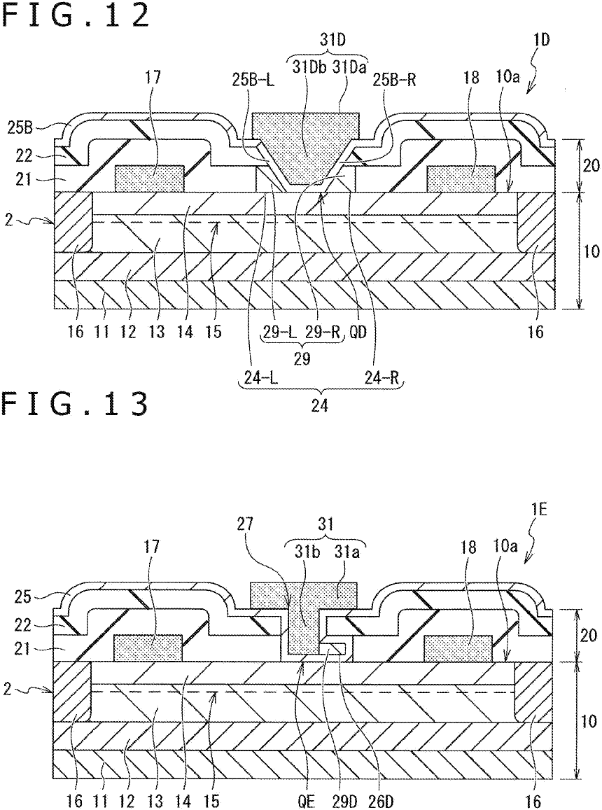

As depicted in FIG. 13, a semiconductor device 1E according to a fifth embodiment of the present technology basically has a configuration similar to the configuration of the semiconductor device 1A of the first embodiment described above, and includes a field effect transistor QE instead of the field effect transistor QA of the first embodiment.

As depicted in FIG. 13, the field effect transistor QE has a bilaterally asymmetric structure in the gate length direction of the gate electrode 31. An embedded film 29E is provided on one of one side surface side and the other side surface side of the gate electrode 31 (drain electrode side), while the embedded film 29E is not provided on the other of the one side surface side and the other side surface side (source electrode side).

Concerning the pair of main electrodes 17 and 18 functioning as a source electrode and a drain electrode here, the main electrode 17 functions as a source electrode, while the main electrode 18 functions as a drain electrode in FIG. 13. In this example, the one side surface side (left side) of the gate electrode 31 in the gate length direction, where the main electrode 17 as a source electrode is provided, corresponds to the source electrode side, while the other side surface side (right side) of the gate electrode 31 in the gate length direction, where the main electrode 18 as a drain electrode is provided, corresponds to the drain electrode side.

As depicted in FIG. 13, the field effect transistor QE includes a chamber 26E and the embedded film 29E filling the chamber 26E on the drain electrode side of the gate electrode 31, but does not include the chamber 26E and the embedded film 29E on the source electrode side of the gate electrode 31. The source electrode side of the gate electrode 31 includes the first insulation film 21 instead of the chamber 26E and the embedded film 29E.

Note that at least any one of the first modification, the second modification, and the third modification of the first embodiment, the second embodiment, the third embodiment, and the fourth embodiment described above may be applicable to the semiconductor device 1E of the fifth embodiment.

The semiconductor device 1E according to the fifth embodiment also offers advantageous effects similar to those of the semiconductor device 1 of the first embodiment described above.

Moreover, according to the semiconductor device 1E of the fifth embodiment, the embedded film 29E is provided on the drain electrode side, while an ordinary structure is provided on the source electrode side without the embedded film 29E. Accordingly, relief of concentration of an electric field and prevention of a parasitic capacitance increase are simultaneously achievable on the drain electrode side.

Note that the side surface of the embedded film 29D on the gate opening 27 side (the body part 31b side of the gate electrode 31) is also substantially flush with the inner wall surface of the gate opening 27 in the fifth embodiment as depicted in FIG. 13. However, as in the first embodiment described above, a space portion may be formed between the body part 31b of the gate electrode 31 and the embedded film 29D.

### Sixth Embodiment

As depicted in FIG. 14, a semiconductor device 1F according to a sixth embodiment of the present technology basically has a configuration similar to the configuration of the semiconductor device 1A of the first embodiment described above, and includes a field effect transistor QF instead of the field effect transistor QA of the first embodiment.

As depicted in FIG. 14, the field effect transistor QF has a bilaterally asymmetric structure in the gate length direction of the gate electrode 31. An embedded film 29F is provided on one of one side surface side and the other side surface side of the gate electrode 31 (drain electrode side), while a hollow portion 34 is provided on the other of the one side surface side and the other side surface side (source electrode side).

Concerning the pair of main electrodes 17 and 18 functioning as a source electrode and a drain electrode here, the main electrode 17 functions as a source electrode, while the main electrode 18 functions as a drain electrode in FIG. 14. In this example, the one side surface side (left side) of the gate electrode 31 in the gate length direction, where the main electrode 17 as a source electrode is provided, corresponds to the source electrode side, while the other side surface side (right side) of the gate electrode 31 in the gate length direction, where the main electrode 18 as a drain electrode is provided, corresponds to the drain electrode side.

As depicted in FIG. 14, a chamber 26F includes a first portion 26F-L provided on the source electrode side of the gate electrode 31, and a second portion 26F-R provided on the drain electrode side of the gate electrode 31. The inside of the second portion 26F-R of the chamber 26F provided on the drain electrode side of the gate electrode 31 is filled with the embedded film 29F. On the other hand, the inside of the first portion 26F-L of the chamber 26F provided on the source electrode side of the gate electrode 31 is not filled with the embedded film 29E. Instead, the hollow portion 34 is provided.

Note that at least any one of the first modification, the second modification, and the third modification of the first embodiment, the second embodiment, the third embodiment, and the fourth embodiment described above may be applicable to the semiconductor device 1F of the sixth embodiment.

The semiconductor device 1F according to the sixth embodiment also offers advantageous effects similar to those of the semiconductor device 1A of the first embodiment described above.

Moreover, according to the semiconductor device 1F of the sixth embodiment, the embedded film 29F is provided on the drain electrode side, while the hollow portion 34 is provided on the source electrode side. Accordingly, relief of concentration of an electric field and prevention of a parasitic capacitance increase are simultaneously achievable on the drain electrode side.

Note that the side surface of the embedded film 29F on the gate opening 27 side (the body part 31b side of the gate electrode 31) is also substantially flush with the inner wall surface of the gate opening 27 in the sixth embodiment as depicted in FIG. 14. However, as in the first embodiment described above, a space portion may be produced between the body part 31b of the gate electrode 31 and the embedded film 29F.

### Seventh Embodiment

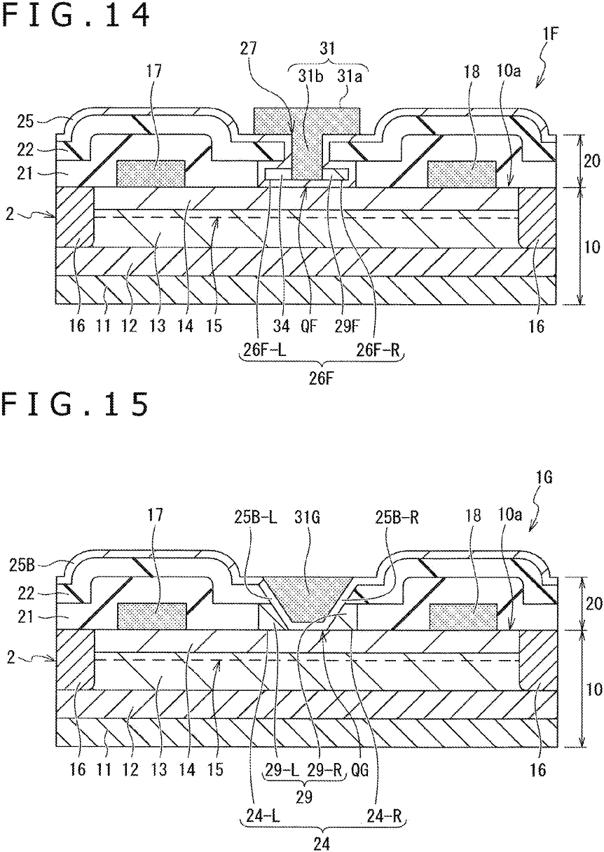

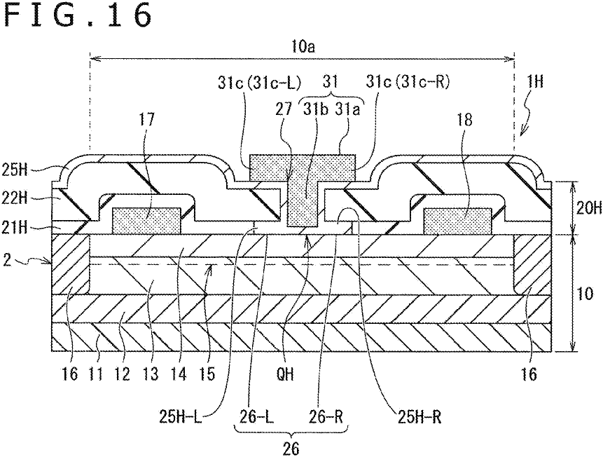

As depicted in FIG. 15, a semiconductor device 1G according to a seventh embodiment of the present technology basically has a configuration similar to the configuration of the semiconductor device 1D of the fourth embodiment described above, and includes a field effect transistor QG instead of the field effect transistor QD of the fourth embodiment. Moreover, the field effect transistor QG of the seventh embodiment basically has a configuration similar to the configuration of the field effect transistor QD of the fourth embodiment described above, and has a different configuration of the gate electrode.

Specifically, as depicted in FIG. 12, the gate electrode 31D of the field effect transistor QD of the fourth embodiment described above includes the head part 31 Da located on the insulation layer 20, and the body part 31Db extending from the head part 31 Da toward the main surface of the semiconductor base 10. In addition, the head part 31 Da has a larger width than the width of the body part 31Db.

On the other hand, as depicted in FIG. 15, the gate electrode 31G of the field effect transistor QG according to the seventh embodiment is embedded in a gate opening of the insulation layer 20. In addition, similarly to the body part 31Db of the gate electrode 31D depicted in FIG. 12, the gate electrode 31G has an inverted tapered shape having two side surfaces which are located at positions opposite to each other in the gate length direction, and are inclined in such directions as to form an acute angle on the interior angle side by these two side surfaces and the main surface of the semiconductor base 10.

According to the field effect transistor QG of the seventh embodiment, capacitance between the gate electrode 31G and the semiconductor base 10 similarly increases as the distance between the gate electrode 31G and the semiconductor base 10 decreases. Accordingly, the semiconductor device 1G of the seventh embodiment also offers advantageous effects similar to those of the fourth embodiment described above.

### Eighth Embodiment

Described in an eighth embodiment will be a case where the third insulation film is adopted as an embedded film and a gate insulation film.

### <<Configuration of Semiconductor Device>>

As depicted in FIG. 16, a semiconductor device 1H according to an eighth embodiment of the present technology basically has a configuration similar to the configuration of the semiconductor device 1A of the first embodiment described above, and includes a field effect transistor QH instead of the field effect transistor QA of the first embodiment.

As depicted in FIG. 16, the field effect transistor QH includes a semiconductor layer 20H instead of the semiconductor layer 20 of the field effect transistor QA of the first embodiment described above and depicted in FIG. 3. In addition, similarly to the field effect transistor QA of the first embodiment, the field effect transistor QH includes the pair of main electrodes regions 17 and 18 functioning as a source region and a drain region, the chamber 26 provided in the insulation layer 20H between the pair of main electrode regions 17 and 18, and the gate electrode 31 including the head part 31a and the body part 31b.

As depicted in FIG. 16, the insulation layer 20H includes a first insulation film 21H formed on the main surface of the semiconductor base 10, a second insulation film 22H formed on the first insulation film 21H, and a third insulation film 25H formed on the second insulation film 22H. For example, the first insulation film 21H includes an aluminum oxide (Al₃O₂) film. For example, the second insulation film 22H includes a silicon oxide (SiO₂) film having etching selectivity higher than etching selectivity of the first insulation film 21H. For example, the first insulation film 21H has a film thickness ranging from 5 nm to 100 nm, such as a film thickness of 10 nm. For example, the second insulation film 22H has a film thickness ranging from 10 nm to 150 nm, such as a film thickness of 40 nm. Moreover, the first insulation film 21H has a relative permittivity equal to or higher than a relative permittivity of the second insulation film 22H. For example, in a case where the first insulation film 21H and the second insulation film 22H include an aluminum oxide film and a silicon oxide film, respectively, the first insulation film 21H has a higher relative permittivity than the second insulation film 22H.

The insulation layer 20H has the chamber 26 similarly to the insulation layer 20 of the first embodiment described above. As described above, the chamber 26 is formed by withdrawal of the first insulation film 21H by side etching performed when the gate opening 27 defining the gate length of the gate electrode 31 is formed in the insulation layer 20H. Similarly to the chamber 26 of the first embodiment described above, a planar pattern of the chamber 26 of the eighth embodiment as viewed in the plan view and explained with reference to FIG. 2 of the first embodiment is an annular planar pattern surrounding the body part 31b of the gate electrode 31. Accordingly, as depicted in FIG. 16, the chamber 26 of the eighth embodiment similarly includes the first portion 26-L located on one side surface side of the body part 31b (left side in FIG. 3), and the second portion 26-R located on the other side surface side of the body part 31b (right side in FIG. 3) in the gate length direction of the gate electrode 31.

As depicted in FIG. 16, the chamber 26 has a width larger than each width of the body part 31b of the gate electrode 31 and the gate opening 27 in the gate length direction of the gate electrode 31. Moreover, the chamber 26 has a width smaller than a width of the head part 31a of the gate electrode 31 in the gate length direction of the gate electrode 31. In other words, a contour of the chamber 26 as viewed in the plan view is located outside a contour of the gate opening 27 but inside a contour of the head part 31a of the gate electrode 31.

As depicted in FIG. 16, the third insulation film 25H is so formed as to cover the first insulation film 21H, the second insulation film 22H, and the main surface of the semiconductor base 10 (barrier layer 14) within the chamber 26. The third insulation film 25H includes a material having a property of insulation from the barrier layer 14 (the main surface of the semiconductor base 10), the first insulation film 21H, and the second insulation film 22H which are exposed to the chamber 26, protecting the barrier layer 14 from impurities such as ions, and forming a preferable interface with the barrier layer 14 to reduce deterioration of characteristics of the device. For example, the third insulation film 25H includes laminated films of an Al₂O₃ film or a hafnium oxide (HfO₂) film each having a film thickness of approximately 10 nm and laminated in this order from the main surface side of the semiconductor base 10. The third insulation film 25H may include a single film of Al₂O₃ or HfO₂.

The third insulation film 25H is provided between the first insulation film 21H and the body part 31b of the gate electrode 31, and between the main surface of the semiconductor base 10 (barrier layer 14) and the body part 31b of the gate electrode 31 in the gate length direction of the gate electrode 31. Moreover, the third insulation film 25H has a relative permittivity equal to or higher than a relative permittivity of the second insulation film 22H similarly to the embedded insulation film 29 of the first embodiment described above. In addition, it is preferable that the third insulation film 25H have a relative permittivity higher than the relative permittivity of the second insulation film 22H, and equal to or higher than a relative permittivity of the first insulation film 21H, similarly to the embedded film 29 of the first embodiment described above.

The third insulation film 25H fills the chamber 26. In other words, the third insulation film 25H is embedded in the chamber 26. A planar pattern of the third insulation film 25H filling the chamber 26 as viewed in the plan view is an annular planar pattern surrounding the body part 31b of the gate electrode 31. Accordingly, as depicted in FIG. 16, the third insulation film 22H includes a first portion 25H-L filling the first portion 26-L of the chamber 26, and a second portion 25H-R filling the second portion 26L of the chamber 26, in the gate length direction of the gate electrode 31. In other words, the first portion 25H-L of the third insulation film 25H is embedded in the first portion 26L of the chamber 26, while the second portion 25H-R of the third insulation film 25H is embedded in the second portion 26R of the chamber 26. The first portion 25H-L and the second portion 25H-R of the third insulation film 25H each function as the embedded insulation film 29 of the first embodiment described above. According to the eighth embodiment, the chamber 26 is filled with the third insulation film 25H, instead of the embedded insulation film 29.

The third insulation film 25H provided between the main surface of the semiconductor base 10 (barrier layer 14) and the body part 31b of the gate electrode 31 functions as a gate insulation film. In other words, in the eighth embodiment, the third insulation film 25H is adopted as an embedded film and a gate insulation film.

As depicted in FIG. 17, the third insulation film 25H provided between the first insulation film 21H and the body part 31b of the gate electrode 31, i.e., the first portion 25H-L and the second portion 25H-R of the third insulation film 25H, each have a plurality of layers. Moreover, each of the first portion 25H-L and the second portion 25H-R of the third insulation film 25H is folded. According to the eighth embodiment, each of the first portion 25H-L and the second portion 25H-R of the third insulation film 25H has two layers.

As depicted in FIG. 17, it is preferable that a film thickness t1 of a single layer of the third insulation film 25H between the first insulation film 25H and the body part 31b of the gate electrode 31 be a half of or larger than a film thickness t2 of the first insulation film 21H. In other words, it is preferable that the film thickness of the third insulation film 25H between the main surface of the semiconductor base 10 and the body part 31b of the gate electrode 31 be a half of or larger than the film thickness of the first insulation film 21.

Moreover, the third insulation film 25H between the first insulation film 21H and the body part 31b of the gate electrode 31 is preferably configured such that the width of the third insulation film 25H in the gate length direction of the gate electrode 31 is equal to or larger than the film thickness of the first insulation film 21H.

As depicted in FIG. 17, the third insulation film 25H is also provided between the second insulation film 22H and the body part 31b of the gate electrode 31. In other words, the field effect transistor QH of the eighth embodiment includes the third insulation film 25H between the semiconductor base 10 and the second insulation film 22H.

### <<Manufacturing Method of Semiconductor Device>>

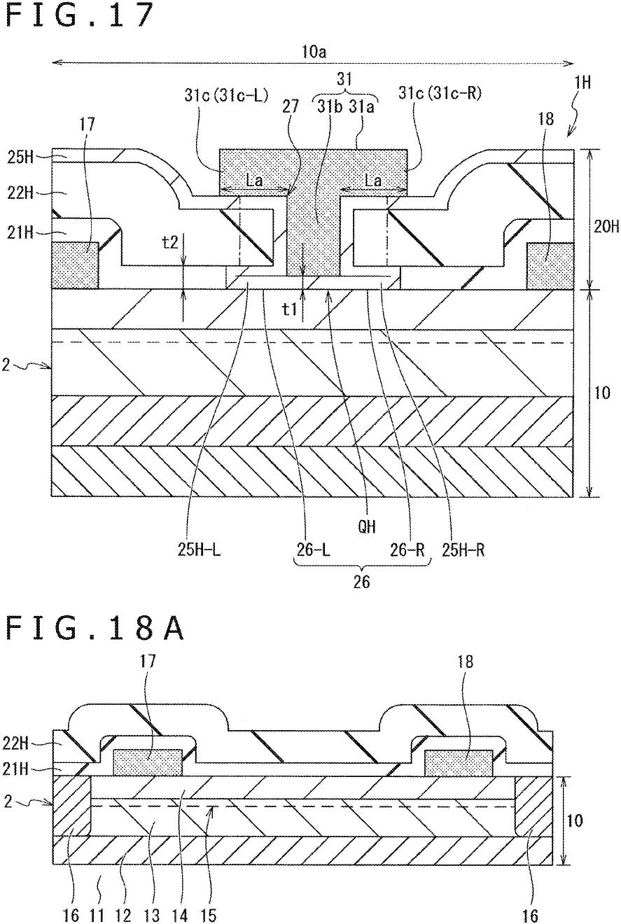

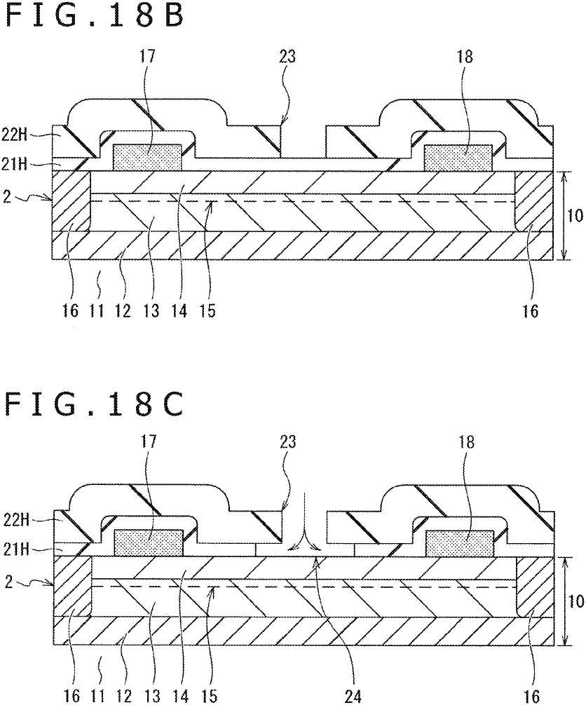

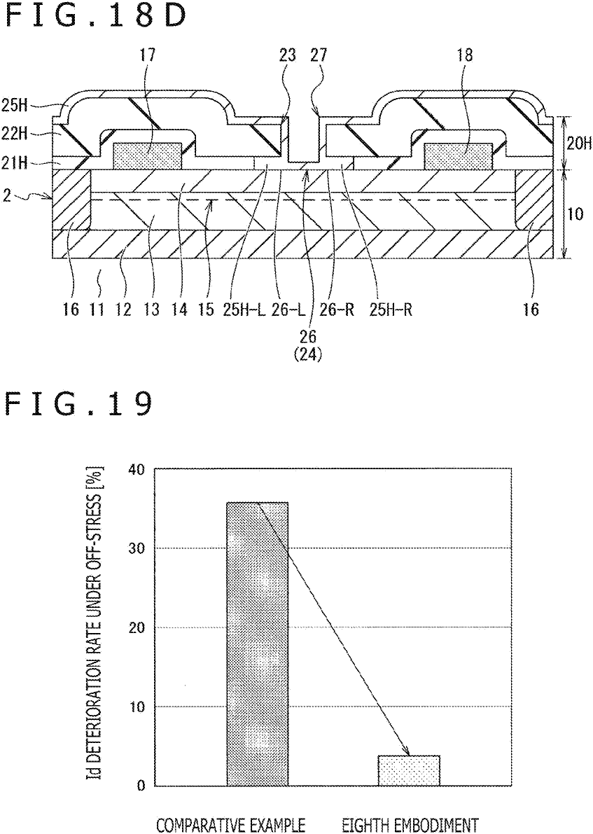

A manufacturing method of the semiconductor device according to the eighth embodiment will subsequently be described with reference to FIGS. 18A to 18D.

Initially, steps similar to the steps depicted in FIGS. 6A to 6C of the first embodiment are performed to form the pair of main electrodes 17 and 18, the first insulation film 21H, the second insulation film 22H, and others on the main surface of the semiconductor base 10, as depicted in FIG. 18A. The second insulation film 22H includes an insulation film having etching selectivity higher than etching selectivity of the first insulation film 21H. For example, an aluminum oxide (Al₂O₃) film is formed as the first insulation film 21H through the ALD, and a silicon oxide (SiO₂) film is formed as the second insulation film 22H through the CVD. Moreover, the first insulation film 21H has a film thickness smaller than the film thickness of the second insulation film 22H. For example, the first insulation film 21H has a film thickness of approximately 10 nm, while the second insulation film 22H has a film thickness of approximately 40 nm. Further, the first insulation film 21H preferably has a film thickness smaller than a thickness twice larger than the film thickness of the third insulation film 25H described below.

By this step, the active region 10a of the main surface of the semiconductor base 10 is covered with the first insulation film 21H and the second insulation film 22H.

Subsequently, as depicted in FIG. 18B, the opening 23 is formed in the second insulation film 22H on the active region 10a of the main surface of the semiconductor base 10. The opening 23 is formed by selectively etching the second insulation film 22H with use of a known photolithography technology, and known dry etching having high directivity as an anisotropic etching technology.

The opening 23 is formed between the pair of main electrodes 17 and 18 in the plan view, and formed in a long-shaped planar pattern extending in the long direction of the pair of main electrodes 17 and 18. The width of the opening 23 formed herein in the gate length direction defines the width of the gate opening 27 in the gate length direction as an opening formed in a step described below (see FIG. 18D). In addition, this width of the gate opening 27 in the gate length direction defines the width of the gate electrode 31 in the gate length direction as a gate electrode 31 formed in a step described below.

Note that the opening 23 having a depth larger than the film thickness of the second insulation film 22H may be formed by over-etching which selectively removes the second insulation film 22H side of the first insulation film 21H such that the first insulation film 21H remains on a bottom portion of the opening 23.

Subsequently, as depicted in FIG. 18C, the chamber 24 having a larger width than the opening 23 is formed by etching the first insulation film 21H on the active region 10a of the semiconductor base 10 with use of the opening 23.

Etching of the first insulation film 21H is achieved by isotropic wet etching which gives less damage to the main surface of the semiconductor base 10, i.e., the surface of the barrier layer 14. At this time, the chamber 24 is formed by withdrawal of the first insulation film 21H caused by side etching applied to the first insulation film 21H. The wet etching of the first insulation film 21H is performed under such a condition that etching selectivity of the first insulation film 21H is securable for the second insulation film 22H. Specifically, wet etching of the first insulation film 21H is performed under such a condition of a higher wet etching rate than that rate of the second insulation film 22H. Higher selectivity is more preferable. For example, etching is performed under such a condition that the ratio of the etching selectivity of the first insulation film 21H to the etching selectivity of the second insulation film 22H is set to 10 or more to 1.

Subsequently, as depicted in FIG. 18D, the main surface of the semiconductor base 10 (the surface of the barrier layer 14) within the chamber 24 is covered with the third insulation film 25H having a relative permittivity equal to or higher than a relative permittivity of the second insulation film 22H. In addition, a region corresponding to withdrawal of the first insulation film 21H as a result of wet etching, i.e., a space region between the main surface of the semiconductor base 10 and the second insulation film 22H, is filled with the third insulation film 25H. For example, the third insulation film 25H is formed by an Al₂O₃ film, an HfO₂ film, or the like formed through the ALD. The ALD is capable of forming a homogeneous film, and therefore, the exposed surfaces of the main surface of the semiconductor base 10 (barrier layer 14), the first insulation film 21H, and the second insulation film 22H are covered with the homogeneous third insulation film 25H. Accordingly, by accumulation of the third insulation film 25H having a film thickness t1 equal to or larger than a half of a film thickness t2 of the first insulation film 21H, the surface of the semiconductor base 10 (the surface of the barrier layer 14) within the chamber 24 is covered with the third insulation film 25H, and also the space region between the main surface of the semiconductor base 10 and the second insulation film 22H within the chamber 24 can be filled with the third insulation film 25H.

In this step, the first insulation film 21H, the second insulation film 22H, and the main surface of the semiconductor base 10 (the surface of the barrier layer 14) within the chamber 24 are covered with the third insulation film 25H. In addition, the surface of the second insulation film 22H and the side surface of the second insulation film 22H within the opening 23 are covered with the third insulation film 25H.

Moreover, in this step, the insulation layer 20H including the first insulation film 21H, the second insulation film 22H, and the third insulation film 25H is formed on the active region 10a of the semiconductor base 10. Accordingly, the upper part of the active region 10a of the semiconductor base 10 including the pair of main electrodes 17 and 18 is covered with the insulation layer 20H.

Moreover, the chamber 26 which has the inner surface covered with the third insulation film 25H is formed in this step.

Further, the respective side walls of the opening 23 in the second insulation film 22H are covered with the third insulation film 25H in this step. Accordingly, the gate opening 27 which has an opening width smaller than the width of the opening 23 is formed. The width of the gate opening 27 in the gate length direction defines the width of the gate electrode 31 in the gate length direction as a gate electrode formed in a step described below.

Thereafter, a step similar to the step depicted in FIG. 6I of the first embodiment is performed to form the gate electrode 31. In this manner, manufacture of the field effect transistor QH depicted in FIGS. 16 and 17 is substantially completed.

### [Advantageous Effects of Eighth Embodiment]

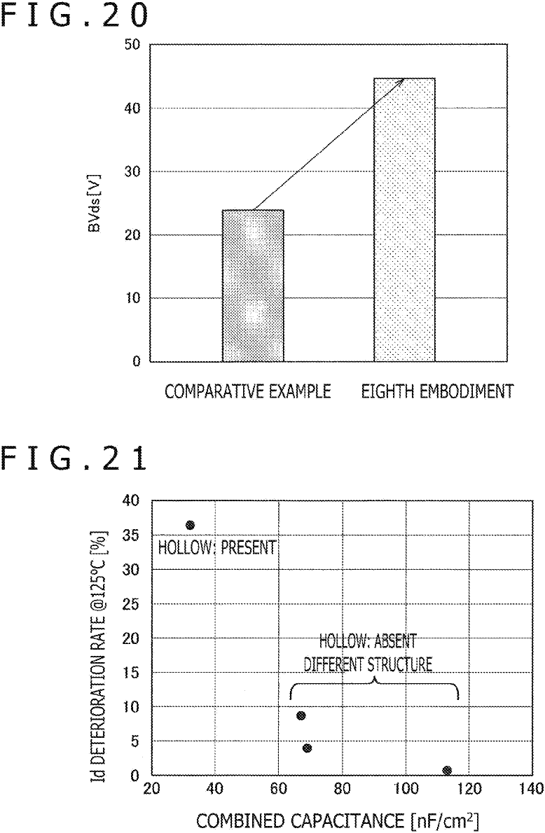

Main advantageous effects of the eighth embodiment will subsequently be described with reference to FIGS. 19, 20, and 21.

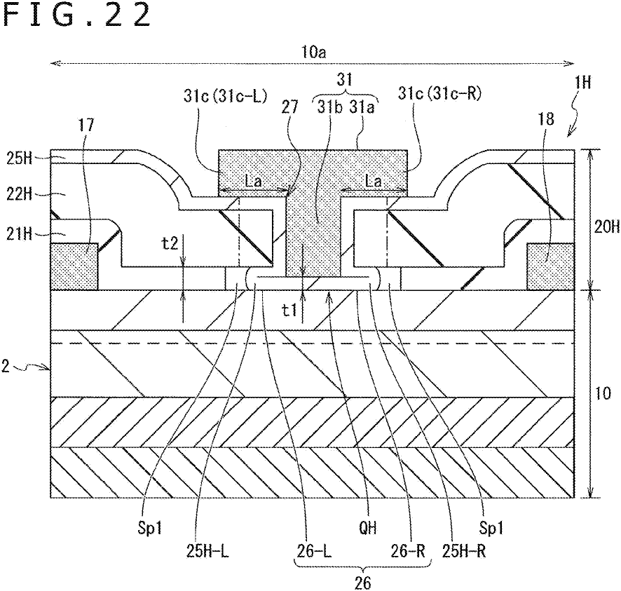

Each of FIGS. 19 and 20 is a graph comparing characteristics of a field effect transistor which has a space portion (hollow portion) on the side of a gate electrode according to a comparative example and the field effect transistor QH of the eighth embodiment.

FIG. 19 compares each Id deterioration rate obtained at a high temperature (125° C.) where a drain-lag appears to be more severe, and at a low voltage of Vd = 1.5 V. As apparent from FIG. 19, the field effect transistor QH of the eighth embodiment which has achieved electric field relief considerably reduces a drain-lag.

Moreover, FIG. 20 presents a result of comparison of breakdown voltage (BVds). According to the field effect transistor QH of the eighth embodiment, electric field relief achieved at an end of the body part 31b of the gate electrode 31 considerably contributes to the breakdown voltage as well. Accordingly, as can be seen from the figures, the drain-lag and the breakdown voltage, each only having a trade-off relation by substrate design, can be both supported.

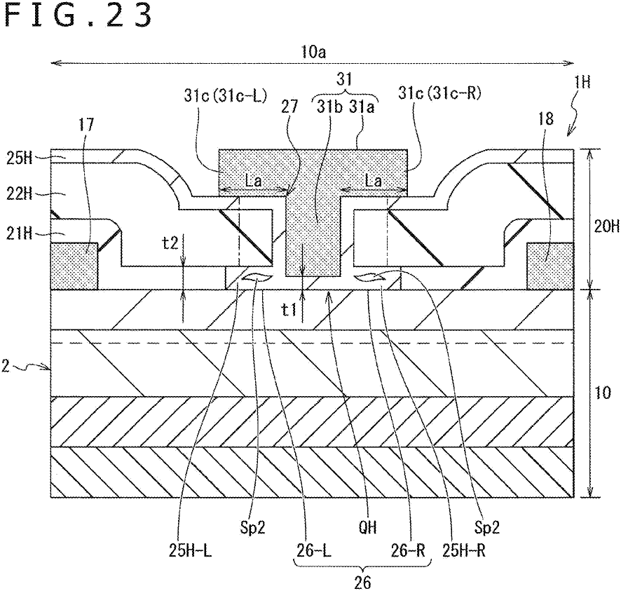

FIG. 21 is a graph presenting a relation between combined capacitance in the longitudinal direction from the projected portions 31c of the gate electrode 31 up to the main surface of the semiconductor base 10 (barrier layer 14) and an Id deterioration rate at 125° C.

As apparent from FIG. 21, there is a correlation between the combined capacitance and the Id deterioration rate. It is obvious that the field plate effect increases and contributes to electric field relief by filling the chamber 26 (hollow) on the side of the body part 31b of the gate electrode 31 with the third insulation film 25H having a high permittivity.

Accordingly, the semiconductor device 1H according to the eighth embodiment also offers advantageous effects similar to those of the semiconductor device 1A of the first embodiment described above.

Further, manufacture of the semiconductor device 1H of the eighth embodiment is similar to the manufacture of the first embodiment described above in that the third insulation film 25H is formed after withdrawal of the first insulation film 21H caused by double-step etching including dry etching and wet etching. However, the chamber (hollow portion) 26 is isotropically filled with the third insulation film 25H due to a film thickness relation between the first insulation film 21H and the third insulation film 25H. In this manner, the necessity of forming a new insulation film (embedded insulation film 29) as in the first embodiment is eliminated, and therefore, the number of manufacturing steps can be made smaller than that number in the first embodiment described above. Accordingly, cost reduction of the semiconductor device 1H is achievable. Moreover, according to the first embodiment described above, a small hollow (space portion) is formed in some cases at the body part 31a side end of the gate electrode 31 during wet etching of the embedded insulation film 29. However, such a small hollow described above is not formed in the eighth embodiment. Accordingly, the field effect further increases at a position where electric field concentration is an important factor.

In addition, in the case of the third insulation film 25H formed through the ALD, the depth side of the chamber 24 (26) may not be filled (completely closed) if the entrance thereof is initially closed. However, sufficient effects can be obtained when the gate electrode 31 on the body part 31a side, which has a dominant influence on reduction of fluctuation of characteristics and improvement of breakdown voltage, is closed.

Further, while each of the first portion 26-L and the second portion 26-R of the chamber 26 is filled with the third insulation film 25H in the eighth embodiment, such a configuration that at least any one of the first portion 26-L and the second portion 26-R of the chamber 26 is filled with the third insulation film 25H is also adoptable. In a case where any one of the first portion 26-L and the second portion 26-R of the chamber 26 is filled with the third insulation film 25H, it is preferable that the chamber 26 located on the side of the main electrode, which is one of the pair of main electrodes 17 and 18 and functions as a drain electrode, be filled with the third insulation film 25H.

In addition, while the embedded insulation film filling the chamber 26 is expressed as the third insulation film 22H in the eighth embodiment, the third insulation film 22H may be expressed as the embedded insulation film 22H.

### [Modification of Eighth Embodiment]

According to the eighth embodiment described above, a case in which the chamber 26 is filled with the third insulation film 25H has been described. However, the present technology is not limited to the eighth embodiment. For example, as depicted in FIG. 22 presenting a modification 8-1 of the eighth embodiment, space portions Sp1 may be present between the first insulation film 21H and the third insulation film 25H.

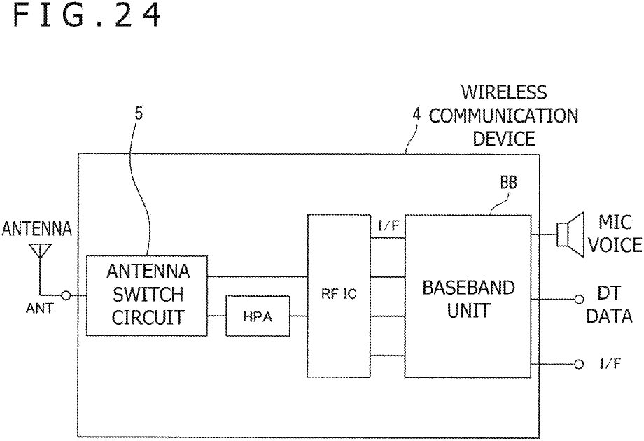

Moreover, as depicted in FIG. 23 presenting a modification 8-2 of the eighth embodiment, space portions Sp2 may be present in the third insulation film 25H between the first insulation film 21H and the body part 31b of the gate electrode 31.

Note that, in the first embodiment to the eighth embodiment described above, there has been described a case where the pair of main electrodes 17 and 18 are formed before the insulation layer 20 or 20H is formed. However, the present technology is not limited to this case. For example, the present technology is also applicable to a case where the pair of main electrodes 17 and 18 are formed after the insulation layer 20 or 20H is formed.

Moreover, in the first embodiment to the seventh embodiment described above, there has been described a case where the insulation layer 20 has the first insulation film 21, the second insulation film 22, and the third insulation film 25. However, the present technology is not limited to this case. For example, the present technology is also applicable to a case of an insulation layer including the first insulation film 21 and the second insulation film 22 other than the third insulation film 25.

Further, according to the first embodiment to the eighth embodiment described above, each layer in an upper part of the substrate 11 includes an AaN-based compound semiconductor. However, the present technology is not limited to this configuration. For example, a compound semiconductor such as GaAs, or a semiconductor layer such as silicon may be adopted.

In addition, according to the first embodiment to the eighth embodiment described above, there has been described the semiconductor device having the one semiconductor chip including the high-frequency power amplifier unit PA, the high-frequency low noise amplifier unit LNA, the high-frequency filter unit BRF, and the high-frequency switch units SW thereon. However, the present technology is not limited to this case. For example, the present technology is applicable to a semiconductor device having a single structure where one field effect transistor is mounted on one semiconductor chip.

### (Application Example)

FIG. 24 depicts an example of a configuration of a wireless communication device as an electronic apparatus to which the semiconductor device of the present technology is applied. For example, a wireless communication device 4 is a cellular phone system which has multiple functions such as voice communication, data communication, and LAN connection. For example, the wireless communication device 4 includes an antenna ANT, an antenna switch circuit 5, a high-power amplifier HPA, a high-frequency integrated circuit RFIC (Radio Frequency Integrated Circuit), a baseband unit BB, a voice output unit MIC, a data output unit DT, and an interface unit I/F (e.g., wireless LAN (W-LAN; Wireless Local Area Network), Bluetooth (registered trademark), and others). The high-frequency integrated circuit RFIC and the baseband unit BB are connected to each other via the interface unit I/F. For example, the antenna switch circuit 5 or the high-power amplifier HPA includes a semiconductor device which includes any of the field effect transistors QA, QA₁, QA₂, QA₃, and QB to QH described above.

According to the wireless communication device 4, during transmission, i.e., in a case of output of a transmission signal from a transmission system of the wireless communication device 4 to the antenna ANT, the transmission signal output from the baseband unit BB is output to the antenna ANT via the high-frequency integrated circuit RFIC, the high-power amplifier HPA, and the antenna switch circuit 5.

During reception, i.e., in a case of input of a signal received by the antenna ANT to a reception system of the wireless communication device, the reception signal is input to the baseband unit BB via the antenna switch circuit 5 and the high-frequency integrated circuit RFIC. The signal processed by the baseband unit BB is output from the output units such as the voice output unit MIC, the data output unit DT, and the interface unit I/F.

The wireless communication device 4 at least includes a semiconductor device which has any of the field effect transistors QA, QA₁, QA₂, QA₃, and QB to QH described above.

Note that the present technology may also have following configurations.

A semiconductor device including:
a field effect transistor mounted on a semiconductor base,
in which the field effect transistor includes
   an insulation layer that includes a first insulation film provided on a main surface of the semiconductor base, and a second insulation film provided on the first insulation film and having etching selectivity higher than etching selectivity of the first insulation film,
   a gate electrode that has a head part located on the insulation layer, and a body part extending from the head part toward the main surface of the semiconductor base, and that is configured such that the head part has a width larger than a width of the body part, and
   an embedded film provided between the first insulation film and the body part of the gate electrode in a gate length direction of the gate electrode, and having a relative permittivity equal to or higher than a relative permittivity of the second insulation film.

The semiconductor device according to (1) described above,

in which the relative permittivity of the embedded film is higher than the relative permittivity of the second insulation film.

The semiconductor device according to (1) described above,

in which the relative permittivity of the embedded film is equal to or higher than a relative permittivity of the first insulation film.

The semiconductor device according to any one of (1) to (3) described above,

in which the embedded film is provided between the head part of the gate electrode and the semiconductor base.

The semiconductor device according to any one of (1) to

described above,

in which the embedded film includes a material different from a material of the first insulation film.

The semiconductor device according to any one of (1) to (5) described above,
in which the first insulation film includes an aluminum oxide film, and
the embedded film includes at least any of a zirconium oxide film, a lanthanum oxide film, and an yttrium oxide film.

The semiconductor device according to any one of (1) to (4) described above,

in which the embedded film includes a material identical to a material of the first insulation film.

The semiconductor device according to any one of (1) to (4) described above,

in which each of the first insulation film and the embedded film includes an aluminum oxide film.

The semiconductor device according to any one of (1) to (8) described above,

in which the field effect transistor includes a space portion formed at least any one of between the embedded film and the body part of the gate electrode and inside the embedded film.

The semiconductor device according to any one of (1) to (9) described above,

in which the field effect transistor includes the embedded film formed on at least any one of one side surface side and the other side surface side of the body part of the gate electrode in the gate length direction of the gate electrode.

The semiconductor device according to any one of (1) to (10) described above,

in which the field effect transistor includes the embedded film on the one side surface side of the body part of the gate electrode in the gate length direction of the gate electrode, and a hollow portion between the other side surface side of the body part of the gate electrode and the first insulation film.

The semiconductor device according to any one of (1) to (10) described above,

in which a width of the body part of the gate electrode in the gate length direction decreases from the head part toward the main surface of the semiconductor base.

The semiconductor device according to any one of (1) to (12) described above,

in which the field effect transistor includes a third insulation film between the first insulation film and the embedded film.

The semiconductor device according to any one of (1) to (12) described above,

in which the field effect transistor includes a third insulation film between the embedded film and the gate electrode.

The semiconductor device according to any one of (1) to (12) described above,

in which the field effect transistor includes a third insulation film between the main surface of the semiconductor base, and the embedded film and the first insulation film.

The semiconductor device according to any one of (1) to (12) described above,

in which the field effect transistor includes a third insulation film between the body part of the gate electrode and the main surface of the semiconductor base.

The semiconductor device according to (1) described above,

in which the embedded film is also provided between the semiconductor base and the body part of the gate electrode.

A manufacturing method of a semiconductor device, including:
forming a first insulation film on a main surface of a semiconductor base;
forming a second insulation film on the first insulation film, the second insulation film having etching selectivity higher than etching selectivity of the first insulation film;
forming an opening by selectively removing the second insulation film;
forming a chamber that has a width larger than a width of the opening by etching that selectively removes the first insulation film with use of the opening; and
forming an embedded film that has a relative permittivity equal to or higher than a relative permittivity of the second insulation film in the chamber between the semiconductor base and the second insulation film.

An electronic apparatus including:
a semiconductor device having a field effect transistor,
in which the field effect transistor includes
   an insulation layer that includes a first insulation film provided on a main surface of the semiconductor base, and a second insulation film provided on the first insulation film and having etching selectivity higher than etching selectivity of the first insulation film,
   a gate electrode that has a head part located on the insulation layer, and a body part extending from the head part toward the semiconductor base, and that is configured such that the head part has a width larger than a width of the body part, and
   an embedded film provided between the first insulation film and the body part of the gate electrode in a gate length direction of the gate electrode, and having a relative permittivity equal to or higher than a relative permittivity of the second insulation film.

A semiconductor device including:
a field effect transistor mounted on a semiconductor base,
in which field effect transistor includes
   an insulation layer that includes a first insulation film provided on a main surface of the semiconductor base, and a second insulation film provided on the first insulation film and having etching selectivity higher than etching selectivity of the first insulation film,
   a gate electrode that has a head part located on the insulation layer, and a body part extending from the head part toward the main surface of the semiconductor base, and that is configured such that the head part has a width larger than a width of the body part, and
   a third insulation film provided between the first insulation film and the body part of the gate electrode and between the semiconductor base and the body part of the gate electrode in a gate length direction of the gate electrode, and having a relative permittivity equal to or higher than a relative permittivity of the second insulation film.

The semiconductor device according to (20) described above,

in which the third insulation film between the first insulation film and the body part of the gate electrode has a plurality of layers.

The semiconductor device according to (20) or (21) described above,

in which the third insulation film between the first insulation film and the body part of the gate electrode is folded.

The semiconductor device according to any one of (20) to (22) described above,

in which the third insulation film between the semiconductor base and the body part of the gate electrode has a film thickness equal to or larger than a half of a film thickness of the first insulation film.

The semiconductor device according to any one of (20) to (23) described above,

in which the third insulation film between the first insulation film and the body part of the gate electrode has a width that is a width in the gate length direction of the gate electrode and is equal to or larger than a film thickness of the first insulation film.

The semiconductor device according to any one of (20) to (24) described above,

in which the third insulation film includes at least any one of an aluminum oxide film and hafnium oxide.

The semiconductor device according to any one of (20) to (25) described above,

in which the third insulation film is also provided between the second insulation film and the body part and the head part of the gate electrode.

The semiconductor device according to any one of (20) to (26) described above,

in which the field effect transistor includes the third insulation film between the semiconductor base and the second insulation film.

The semiconductor device according to any one of (20) to (27) described above,

in which the field effect transistor includes a space portion between the first insulation film and the third insulation film.

The semiconductor device according to any one of (20) to (26) described above,

in which the field effect transistor includes a space portion in the third insulation film between the first insulation film and the body part of the gate electrode.

A manufacturing method of a semiconductor device, including:
forming a first insulation film on a main surface of a semiconductor base;
forming a second insulation film on the first insulation film, the second insulation film having etching selectivity higher than etching selectivity of the first insulation film;
forming an opening by dry etching that selectively removes the second insulation film;
forming a chamber that has a width larger than a width of the opening by wet etching that selectively removes the first insulation film with use of the opening under such a condition that etching selectivity of first insulation film is securable for the second insulation film; and
covering the main surface of the semiconductor base with a third insulation film that has a relative permittivity equal to or higher than a relative permittivity of the second insulation film in the chamber, and filling a space between the main surface of the semiconductor base and the second insulation film with the third insulation film.

An electronic apparatus including:
a semiconductor device having a field effect transistor,
in which the field effect transistor includes
   an insulation layer that includes a first insulation film provided on a main surface of the semiconductor base, and a second insulation film provided on the first insulation film and having etching selectivity higher than etching selectivity of the first insulation film,
   a gate electrode that has a head part located on the insulation layer, and a body part extending from the head part toward the semiconductor base, and that is configured such that the head part has a width larger than a width of the body part, and
   a third insulation film provided between the first insulation film and the body part of the gate electrode in a gate length direction of the gate electrode and between the semiconductor base and the body part of the gate electrode, and having a relative permittivity equal to or higher than a relative permittivity of the second insulation film.

The scope of the present technology is not limited to the exemplary embodiments described and depicted in the drawings, and includes all embodiments offering effects similar to those intended to be offered by the present technology. Moreover, the scope of the present technology is not limited to combinations of characteristics of the invention defined by the claims, and may be defined by any specific desired combinations of characteristics included in all disclosed characteristics.

### REFERENCE SIGNS LIST

1A, 1A₁, 1A₂, 1A₃, 1B, 1C, 1D, 1E, 1F, 1H: Semiconductor device
2: Semiconductor chip
10: Semiconductor base
11: Substrate
12: Buffer layer
13: Channel layer
14: Barrier layer
15: Two-dimensional electron gas layer
16: Non-active region
17, 18: Pair of first main electrodes (source electrode and drain electrode)
20, 20H: Insulation layer
21, 21H: First insulation film
22, 22H: Second insulation film
23: Opening
24, 26, 26C, 26D, 26F: Chamber
25, 25B, 25C, 25H: Third insulation film
27: Gate opening
28: Embedded material
29, 29A₁, 29A₂, 29A₃, 29D, 29E: Embedded film
30: Gate material
31, 31C: Gate electrode
31a: Head part
31b: Body part
31c: Projected portion
32, 33, 33a: Space portion
34: Hollow portion
SW: High-frequency switch unit
BPF: High-frequency filter unit
PA: High-frequency power amplifier unit
LNA: High-frequency low noise amplifier unit
QA, QA₁, QA₂, QA₃, QB, QC, QD, QE, QF, QH: Field effect transistor

1. A semiconductor device comprising:
a field effect transistor mounted on a semiconductor base,
wherein the field effect transistor includes
an insulation layer that includes a first insulation film provided on a main surface of the semiconductor base, and a second insulation film provided on the first insulation film and having etching selectivity higher than etching selectivity of the first insulation film,
a gate electrode that has a head part located on the insulation layer, and a body part extending from the head part toward the main surface of the semiconductor base, and that is configured such that the head part has a width larger than a width of the body part, and
an embedded film provided between the first insulation film and the body part of the gate electrode in a gate length direction of the gate electrode, and having a relative permittivity equal to or higher than a relative permittivity of the second insulation film.

2. The semiconductor device according to claim 1,
wherein the relative permittivity of the embedded film is higher than the relative permittivity of the second insulation film.

3. The semiconductor device according to claim 1,
wherein the relative permittivity of the embedded film is equal to or higher than a relative permittivity of the first insulation film.

4. The semiconductor device according to claim 1,
wherein the embedded film is provided between the head part of the gate electrode and the semiconductor base.

5. The semiconductor device according to claim 1,
wherein the embedded film includes a material different from a material of the first insulation film.

6. The semiconductor device according to claim 1,
wherein the embedded film includes a material identical to a material of the first insulation film.

7. The semiconductor device according to claim 1,
wherein each of the first insulation film and the embedded film includes an aluminum oxide film.

8. The semiconductor device according to claim 1,
wherein the field effect transistor includes a third insulation film between the first insulation film and the embedded film.

9. The semiconductor device according to claim 1,
wherein the field effect transistor includes a third insulation film between the embedded film and the gate electrode.

10. The semiconductor device according to claim 1,
wherein the field effect transistor includes a third insulation film between the main surface of the semiconductor base, and the embedded film and the first insulation film.

11. The semiconductor device according to claim 1,
wherein the field effect transistor includes a third insulation film between the body part of the gate electrode and the main surface of the semiconductor base.

12. The semiconductor device according to claim 1,
wherein the embedded film is also provided between the semiconductor base and the body part of the gate electrode.

13. An electronic apparatus comprising:
a semiconductor device having a field effect transistor,
wherein the field effect transistor includes
an insulation layer that includes a first insulation film provided on a main surface of the semiconductor base, and a second insulation film provided on the first insulation film and having etching selectivity higher than etching selectivity of the first insulation film,
a gate electrode that has a head part located on the insulation layer, and a body part extending from the head part toward the semiconductor base, and that is configured such that the head part has a width larger than a width of the body part, and
an embedded film provided between the first insulation film and the body part of the gate electrode in a gate length direction of the gate electrode, and having a relative permittivity equal to or higher than a relative permittivity of the second insulation film.

14. A semiconductor device comprising:
a field effect transistor mounted on a semiconductor base,
wherein the field effect transistor includes
an insulation layer that includes a first insulation film provided on a main surface of the semiconductor base, and a second insulation film provided on the first insulation film and having etching selectivity higher than etching selectivity of the first insulation film,
a gate electrode that has a head part located on the insulation layer, and a body part extending from the head part toward the main surface of the semiconductor base, and that is configured such that the head part has a width larger than a width of the body part, and
a third insulation film provided between the first insulation film and the body part of the gate electrode and between the semiconductor base and the body part of the gate electrode in a gate length direction of the gate electrode, and having a relative permittivity equal to or higher than a relative permittivity of the second insulation film.

15. The semiconductor device according to claim 14,
wherein the third insulation film between the first insulation film and the body part of the gate electrode is folded.

16. The semiconductor device according to claim 14,
wherein the third insulation film between the semiconductor base and the body part of the gate electrode has a film thickness equal to or larger than a half of a film thickness of the first insulation film.

17. The semiconductor device according to claim 14,
wherein the third insulation film between the first insulation film and the body part of the gate electrode has a width that is a width in the gate length direction of the gate electrode and is equal to or larger than a film thickness of the first insulation film.

18. The semiconductor device according to claim 14,
wherein the third insulation film includes at least any one of an aluminum oxide film and hafnium oxide.

19. The semiconductor device according to claim 14,
wherein the third insulation film is also provided between the second insulation film and the body part and the head part of the gate electrode.

20. The semiconductor device according to claim 14,
wherein the field effect transistor includes the third insulation film between the semiconductor base and the second insulation film.
